(19) United States
(12) Patent Application Publication
(10) Pub. No.: US 2026/0331865 A1
(43) Pub. Date: Oct. 22, 2026

(54) ELECTRO-ABSORPTION MODULATED LASER WITH CONTROLLED OPTICAL BALANCE BETWEEN VERTICALLY INTEGRATED WAVEGUIDES

(71) Applicant: ElectroPhotonic-IC Inc., Kanata (CA)

(72) Inventors: Kirill PIMENOV, Orleans (CA); Yury LOGVIN, Kanata (CA); Vighen PACRADOUNI, Montreal (CA); Lawrence E. TAROF, Kanata (CA)

(21) Appl. No.: 19/185,513

(22) Filed: Apr. 22, 2025

(51) Int. Cl. H01S 5/026; H01S 5/02; H01S 5/10; H01S 5/12; H01S 5/20; H01S 5/22

(52) U.S. Cl. CPC H01S 5/0265; H01S 5/0208; H01S 5/1014; H01S 5/12; H01S 5/2031; H01S 5/22

(57) ABSTRACT

A monolithically integrated electro-absorption modulated laser (EML) fabricated with Multi-Guide Vertical Integration (MGVI) comprises a first optical waveguide, defining a laser and a laterally tapered vertical optical coupler (taper), and a second optical waveguide, comprising an electro-absorption modulator (EAM). The epitaxial layer stack for the DFB laser comprises a balancing layer, comprising a higher index material, e.g. a quaternary composition, positioned above or below the DFB grating of the DFB laser. In combination with the design of the taper, the balancing layer allows for efficient control of laser mode confinement, distributed feedback coupling and control of optical mode transfer between the DFB laser waveguide and the EAM waveguide. Example EML structures are fabricated with III-V semiconductor materials, such an InP-based materials system. Optionally, the EML is monolithically integrated with driver and control electronics, e.g. comprising InP HBTs.

### CROSS-REFERENCE TO RELATED APPLICATION(S)

This application is related to U.S. patent application Ser. No. 19/089,534, filed Mar. 25, 2025, entitled “Vertically Integrated Electro-absorption Modulated Laser”, which is a continuation-in-part of U.S. patent application Ser. No. 17/687,803, filed Mar. 7, 2022, entitled “Vertically integrated Electro-absorption Modulated Laser”, which are incorporated herein by reference in their entirety.

This application is related to U.S. patent application Ser. No. 18/984,180, filed Dec. 17, 2024, entitled “Vertically Integrated Electro-absorption Modulated Laser”, which is a continuation of U.S. patent application Ser. No. 17/687,803, filed Mar. 7, 2022, entitled “Vertically Integrated Electro-absorption Modulated Laser” which are incorporated herein by reference in their entirety.

This application is related to U.S. provisional patent application no. 63/734,954, filed Dec. 17, 2024, entitled “Electro-absorption Modulator and Monolithic Electro-Photonic Circuit comprising an Electro-absorption Modulator and Driver” which is incorporated herein by reference in its entirety.

This application is related to U.S. provisional patent application no. 63/754,106, filed Feb. 5, 2024, entitled “Differential Electro-absorption Modulator System”, which is incorporated herein by reference in its entirety.

### TECHNICAL FIELD

This invention relates to monolithically integrated electro-absorption modulated lasers (EML) comprising a laser and an electro-absorption modulator (EAM), and electro-photonic integrated circuits comprising an EML and driver electronics, fabricated with III-V semiconductor materials, e.g. an Indium Phosphide (InP)-based materials system.

### BACKGROUND

Data may be encoded onto an optical signal by direct modulation of an optical source such as semiconductor laser, referred to as a directly modulated laser (DML), or by external modulation of a continuous wave (CW) optical output of a CW semiconductor laser using an external modulator. External modulators may operate by an electro-optic effect or by electro-absorption.

Electro-optic modulators are based on materials in which the real part of the refractive index changes with the application of an electric field, due to the Pockels effect or Kerr effect. Electro-absorption modulators involve materials in which the imaginary part of the refractive index changes with application of an electric field, based on the Franz-Keldysh effect, or the Quantum Confined Stark Effect (QCSE) in a multi-quantum well (MQW) structure.

Electro-absorption modulators (EAM) are typically more compact than electro-optic modulators, such as MZM (Mach-Zehnder modulators).

Most EAMs today rely on QCSE. For example, QCSE EAMs may have an active optical waveguide length in the order of tens of μm, and can be operated with a drive voltage in the order of 2V. For example, an EAM may be integrated with a CW semiconductor laser to form an electro-absorption modulated laser (EML). An EML may comprise an EAM, an external laser, and driver electronics. The laser and EAM of an EML may be hybrid integrated or monolithically integrated.

Conventional EML assemblies may be made with discrete components, i.e. a separately fabricated DFB laser chip and an EAM chip, which may comprise different semiconductor materials. The laser and the EAM are butt-coupled on a common substrate, and require cooling, e.g. is back-side cooled with a thermoelectric cooler (TEC). Butt-coupling may be achieved, for example, by directly fusing facets of the DFB laser and the EAM, or bonding the facets with an encapsulant or bonding material. However, in EML assemblies of these types of structures, the interface region between the DFB laser and EAM components, particularly when fabricated from semiconductor materials having different crystalline compositions, is a region of high-stress and strain, e.g., due to lattice mismatch, different temperature coefficients of expansion (CTE), and other inherently different characteristics as a function of operating conditions. Thus, these EML assemblies typically have a very narrow operating temperature range, in the order of e.g. ~1 C, even when cooled. For some butt-coupled EML assemblies, it has been reported that reliable operation is limited to ~2000 hrs and failures may occur at <3000 hrs.

As summarized in the above referenced U.S. patent application Ser. No. 17/687,803, in principle, monolithic integration of optical waveguide devices having different waveguide core regions and functions can be achieved in one of the following ways:
a) direct butt-coupling: multiple steps of epitaxial growth, with selective area etching and re-growth, are used to provide the required semiconductor layers for each waveguide device, which are laterally coupled through a common horizontal optical plane on a PIC die;
b) modified butt-coupling: growth of single epitaxial layer stack, with selective area post-growth modification form regions to each waveguide device, which are laterally coupled through a common horizontal optical plane on a PIC die; and
c) evanescent-field coupling: an epitaxial layer stack defines vertically stacked waveguide devices which are vertically coupled through resonant or non-resonant evanescent field coupling.

Fabrication of multi-guide vertical integration (MGVI) structures, which are based on non-resonant evanescent field vertical coupling are described, for example, in: PCT International Patent publication no. WO2013/185218A1 to Tolstikhin, published Dec. 19, 2013, entitled “Space-Wavelength Division Multiplexing Transmitter and Receiver Photonic Integrated Circuits”.

With accelerating demand for high-speed optical transceivers, electro-photonic integrated circuits comprising InP-based materials are promising candidates for delivering desired performance and cost. MGVI using III-V semiconductor materials, such as InP-based materials, provides for vertical integration of a plurality of optical waveguides that provide various functions for optical transmitters and receivers, e.g. light generation, light modulation and absorption.

For example, the above referenced U.S. patent application Ser. No. 17/687,803, filed Mar. 7, 2022, entitled “Vertically integrated Electro-Absorption Modulated Laser” discloses vertical integration of a laser and an EAM using a laterally tapered vertical optical coupler. Laterally tapered vertical optical couplers provide an alternative to conventional butt-coupling of a laser and EAM, offering improved reliability for high power operation over extended lifetimes.

As data communication technology advances, and speed of operation continues to be pushed beyond the current norms, there is a need for EAM and EML which provide improved performance for high-speed modulation, e.g. next generation high-speed modulation schemes such as 112 GB, 224 Gb/s PAM 4 and 224 GB, 448 Gb/s PAM 4 modulation, with applications such as high-speed optical data interconnects within data centers and between data centers, passive optical networks (PON), 5G network communications (i.e. optical core network connected to 5G wireless access), et al.

There is a need for improved or alternative EML, and electro-photonic integrated circuits comprising EML, particularly for applications such as high-speed optical data interconnects.

### SUMMARY OF INVENTION

The present invention seeks to provide improved or alternative monolithically integrated electro-absorption modulated lasers (EML) comprising a laser and an electro-absorption modulator (EAM), and electro-photonic integrated circuits comprising an EML and driver electronics, fabricated with III-V semiconductor materials, e.g. an Indium Phosphide (InP)-based materials system.

Aspects of the invention provide a monolithically integrated electro-absorption modulated laser (EML) fabricated with Multi-Guide Vertical Integration (MGVI) which comprises a first optical waveguide, defining a laser and a laterally tapered vertical optical coupler (taper), and a second optical waveguide, comprising an electro-absorption modulator (EAM). Each waveguide comprises a MQW QCSE active region. The epitaxial layer stack for the DFB laser comprises a balancing layer, comprising a quaternary material positioned above or below the DFB grating of the DFB laser. The balancing layer, in combination with appropriate design of the taper, allows for efficient control of laser mode confinement, distributed feedback coupling and control of optical mode transfer between the DFB laser waveguide and the EAM waveguide. Example EML structures are fabricated with III-V semiconductor materials, such an InP-based materials system. Optionally, the EML is monolithically integrated with driver and control electronics, e.g. comprising InP HBTs.

One aspect provides a monolithically integrated electro-absorption modulated laser (EML) comprising:
a semi-insulating (SI) substrate;
a plurality of semiconductor layers formed on the SI substrate defining first and second optical waveguides that are vertically stacked;
the first optical waveguide (WG1) having a core comprising a first multi-quantum well (MQW) i-region, and upper and lower cladding layers, a part of the first optical waveguide comprising an electro-absorption modulator (EAM);
the second optical waveguide (WG2) having a core comprising a second MQW i-region, and upper and lower cladding layers, a first part of WG2 defining a distributed feedback (DFB) laser comprising a DFB grating, and second part of WG2 defining a laterally tapered vertical optical coupler (taper) extending from an optical output of the laser;
the taper being structured to couple an optical mode from the optical output of the laser to an input of the EAM;
first electrical connections to the laser configured for operating the laser in continuous wave (CW) mode;
second electrical connections to the EAM configured for driving the first EAM; and
wherein at least one of WG1 and WG2 is structured to control confinement of said optical mode in the core of the laser and in the core of the EAM.

For example, at least one of WG1 and WG2 is structured to provide high confinement of said optical mode in the core of the laser, and lower confinement of the optical mode and in the core of the EAM.

An aspect provides monolithically integrated electro-absorption modulated laser (EML) comprising:
a semi-insulating (SI) substrate;
a plurality of semiconductor layers formed on the SI substrate defining first and second optical waveguides that are vertically stacked;
the first optical waveguide (WG1) having a core comprising a first multi-quantum well (MQW) i-region, and upper and lower cladding layers, a part of the first optical waveguide comprising an electro-absorption modulator (EAM);
the second optical waveguide (WG2) having a core comprising a second MQW i-region, and upper and lower cladding layers, a first part of WG2 defining a distributed feedback (DFB) laser comprising a DFB grating, and second part of WG2 defining a laterally tapered vertical optical coupler (taper) extending from an optical output of the laser;
the taper being structured to couple an optical mode from the optical output of the laser to an input of the EAM;
first electrical connections to the laser configured for operating the laser in continuous wave (CW) mode;
second electrical connections to the EAM configured for driving the first EAM;
wherein at least one of WG1 and WG2 comprises a balancing layer of a material having a refractive index selected to control confinement of said optical mode in the core of the laser and in the core of the EAM.

In some embodiments, the balancing layer is provided within WG2, above the first MQW i-region, and has a refractive index selected to provide high confinement of said optical mode within the core of the laser, and lower confinement of said optical mode within the core of the EAM.

In some embodiments, the balancing layer is provided within WG1 and has a refractive index selected to provide high confinement of said optical mode within the core of the laser, and lower confinement of said optical mode within the core of the EAM.

In some embodiments, WG2 comprises the balancing layer, and the balancing layer comprises a material having a refractive index selected to provide a first effective refractive index of WG2 that is greater than a second effective refractive index of WG1. For example, the balancing layer provides an effective refractive index differential Δn between the first and second effective refractive indexes, where Δn is in a range that controls optical coupling of between WG2 and WG1 to provide high optical confinement within the core of the laser and lower optical confinement within the core of the EAM.

In some embodiments, WG2 comprises the balancing layer, and the balancing layer comprises a material having a refractive index selected to increase an effective refractive index of WG2, relative to an effective refractive index of WG1. In some embodiments, WG1 comprises the balancing layer, the balancing layer comprises a material having a refractive index selected to decrease an effective refractive index of WG1 relative to the effective refractive index of WG2.

In some embodiments, wherein the DFB laser comprises a mesa and a ridge, the DFB laser comprises a DFB grating within the mesa, and the balancing layer is within the ridge above the DFB grating and separated from the DFB grating by a spacer layer.

In some embodiments, wherein the DFB laser comprises a mesa and a ridge, the DFB laser comprises a DFB grating within the ridge, and the balancing layer is within a ridge above the DFB grating and separated from the DFB grating by a spacer layer.

In some embodiments, wherein the DFB laser comprises a mesa and a ridge, the DFB laser comprises a DFB grating within the ridge, and the balancing layer is within a ridge below the DFB grating and separated from the DFB grating by a spacer layer.

In some embodiments, wherein the DFB laser comprises a mesa and a ridge, the DFB grating is positioned within the mesa, and the balancing layer is within a ridge above the DFB grating and separated from the grating by a spacer layer, and the balancing layer is undercut relative to the width of the ridge.

In some embodiments, the DFB laser comprises a mesa and a ridge, and the DFB grating is positioned within the mesa, and the balancing layer is within the mesa, above or below the DFB grating.

In some embodiments the monolithically integrated EML comprises third electrical connections to at least part of the taper for biasing the taper.

For example, wherein the third electrical connections comprise a plurality of conductive traces extending laterally across said at least part of the taper.

For example, the taper comprises a first part defined by sidewalls of a laser ridge and a laser mesa of WG2 and a second part defined by sidewalls of WG1.

For example, the taper comprises a first part defined by sidewalls of a laser ridge and a laser mesa of WG2, and a second part defined by sidewalls of WG1, wherein the sidewalls of the WG1 are defined by a trench etched through WG1, wherein the trench is discontinuous to provide bridges for routing of said third electrical connections.

In one aspect, the monolithically integrated EML comprises a passive transition waveguide disposed between WG1 and WG2, the transition waveguide comprising a second laterally tapered vertical optical coupler, the optical output of the laser being optically coupled from the taper of WG2 to the transition waveguide and from the second taper of the transition waveguide to WG1 to the optical input of the EAM.

In an embodiment, WG1 has an effective refractive index greater than the effective refractive index of WG2, and the passive transition waveguide has a non-absorbing core of a material that provide an effective refractive index of the transition waveguide having a value between the effective refractive indexes of WG1 and WG2.

In some embodiments of a monolithically integrated EML an output of the EAM is optically coupled to a passive output waveguide. The EAM may be coupled to a passive output waveguide by vertical or lateral optical coupling.

Monolithically integrated EML of example embodiments may be fabricated with III-V semiconductor materials, such as an InP-based materials system. For example, embodiments are described wherein the SI substrate is Fe-doped InP and the EML is fabricated from an InP-based material system, comprising selected binary, ternary and quaternary and other compositions of In, Ga, As, P, Al and Sb. For example, materials are selected which are lattice-matched or nearly lattice-matched to InP. Electrical interconnections are provided by one of more metallization layers and intermetal dielectric layers of compatible materials.

For example, for a monolithically integrated EML fabricated with an InP-based materials system, the balancing layer is a layer provided within WG2 comprising a material that is lattice matched to InP, or nearly lattice matched to InP, having a refractive index greater than that of InP. The balancing layer may be a layer of a quaternary material, e.g. comprising one of InGaAlAs and InGaAsP.

In another aspect, a monolithically integrated EML as defined herein comprises a second plurality of semiconductor layers formed on the SI substrate comprising electronic circuitry, the electronic circuitry comprising an EAM driver, and the EAM driver being electrically connected to the second electrical interconnections of the EAM and configured to drive the EAM to provide a modulated optical output. In some embodiments, the electronic circuitry comprises a laser driver, the laser driver being electrically connected to the first electrical interconnections of the laser and configured to drive the laser.

Example embodiments are described for implementation a monolithically integrated EML, with and without monolithically integrated electronics comprising a laser driver and EAM drivers, e.g. using an InP-based materials system.

Monolithically integrated EML of example embodiments are described wherein at least one of WG1 and WG2 is structured to balance lateral and vertical confinement of the optical mode in the core of the laser and in the core of the EAM. Appropriate optical balance between the vertically stacked optical waveguides is achieved by elements comprising the epitaxial layer structure (materials and layer thicknesses) of the laser waveguide and the EAM waveguide, the structure of the active waveguide of the laser, the structure of active waveguide of the EAM, and the design of the laterally tapered vertical optical coupler (taper), which may comprise means for biasing at least part of the taper. In some embodiments, a transition waveguide is provided between WG1 and WG2.

In another aspect, there is a provided an optical transmitter comprising a monolithically integrated EML as disclosed herein. The optical transmitter may include monolithically integrated electronic circuitry, e.g. comprising at least one of an EAM driver and a laser driver, and other electronics.

In another aspect, there is provided a method of fabrication of a monolithically integrated EML as disclosed herein. The monolithically integrated EML may include monolithically integrated electronic circuitry, e.g. comprising at least one of an EAM driver and a laser driver, and other electronics.

It will be appreciated that the aspects above and elements of EML of example embodiments can be combined to form combinations not specifically stated in the claims or description.

The foregoing and other features, aspects and advantages will be more apparent from the following detailed description, taken in conjunction with the accompanying drawings, of example embodiments, which description is by way of example only.

### BRIEF DESCRIPTION OF THE DRAWINGS

FIG. 1A is a schematic cross-sectional view of an electro-absorption modulated laser (EML) of an example embodiment comprising a laser and an electro-absorption modulator (EAM) fabricated with a laterally tapered vertical optical coupler;

FIG. 1B is a schematic plan view of the EML of FIG. 1A;

FIG. 1C is a schematic cross-sectional view of a DFB laser with a surface etched grating (SEG)

FIG. 1D is a schematic cross-sectional view of a DFB laser with a buried grating;

FIG. 2A is a schematic cross-sectional view of a monolithic electro-photonic integrated circuit comprising an EM L of an example embodiment comprising a laser and EAM fabricated with a laterally tapered vertical optical coupler, and comprising monolithically integrated driver and control electronics;

FIG. 2B is a schematic plan view of the monolithic electro-photonic integrated circuit comprising the EML of FIG. 2A;

FIG. 3A is a schematic cross-sectional view of an EML of an example embodiment comprising a laser, a transition waveguide, and an EAM, fabricated with laterally tapered vertical optical couplers;

FIG. 3B is a schematic plan view of the EML of FIG. 3A;

FIG. 3C is schematic perspective view of part of the EML of FIG. 3A and FIG. 3B;

FIGS. 4A, 4B, 4C, 4D and 4E are schematic cross-sectional views through sections A-A′ to E-E′ of FIGS. 3B and 3C;

FIG. 5A is a diagram created by optical modelling of an optical mode structure within the laser waveguide of FIG. 4A;

FIG. 5B is a diagram created by optical modelling of an optical mode within the laser waveguide and within the EAM waveguide of FIGS. 4A to 4E, showing vertical transition of the optical mode from the laser waveguide to the EAM waveguide;

FIG. 5C is a diagram created by optical modelling of an optical mode within the laser waveguide and within the EAM waveguide of FIGS. 4A to 4E, showing the optical mode split between the laser waveguide and the EAM waveguide;

FIG. 6 is a schematic perspective view of part of an EML of another example embodiment;

FIG. 7 is another schematic perspective view of part of the EML of FIG. 6;

FIG. 8 is a schematic cross-sectional view of an EML shown in part in FIGS. 6 and 7;

FIG. 9 is schematic perspective view of an epitaxial layer structure for an EML of another example embodiment;

FIG. 10 is schematic perspective view of an epitaxial layer structure for an EML of another example embodiment comprising monolithically integrated electronics layers;

FIG. 11 is schematic perspective view of an epitaxial layer structure for an EML of an example embodiment wherein the laser waveguide comprises a balancing layer comprising a quaternary (Q)-material;

FIG. 12 is schematic cross-sectional view of an epitaxial layer structure for an EML of another example embodiment wherein the laser waveguide comprises comprising a balancing layer of a Q-material;

FIG. 13 is schematic cross-sectional view of view of an epitaxial layer structure for an EML of another example embodiment wherein the laser waveguide comprises comprising a balancing layer of a Q-material;

FIG. 14 is schematic cross-sectional view of view of an epitaxial layer structure for an EML of another example embodiment wherein the laser waveguide comprises comprising a balancing layer of a Q-material;

FIG. 15 is a plot showing taper transfer loss (dB) vs. taper width for EML of two example embodiments wherein the laser waveguide comprises a balancing layer, with and without undercut of the balancing layer;

FIG. 16 is schematic cross-sectional view of view of an epitaxial layer structure for an EML of another example embodiment wherein the laser waveguide comprises a balancing layer;

FIG. 17 is a schematic plan view of the taper region of an EML of an example embodiment;

FIG. 18 is a schematic vertical cross-sectional view through the taper structure of FIG. 17 showing a simulation of an optical mode pattern to illustrate transition of the optical mode from the laser waveguide to the EAM waveguide along the length of the taper;

FIGS. 19A to 19E are schematic cross-sectional views through sections A-A′ to E-E′ of the taper structure shown in FIG. 17;

FIGS. 20A to 20E are schematic cross-sectional views through sections A-A′ to E-E′ as shown in FIGS. 19A to 19E, to illustrate example optical mode shapes at each cross-section;

FIG. 21A is schematic cross-sectional view of view of an epitaxial layer structure for an EML of another example embodiment comprising a laterally coupled passive output waveguide;

FIG. 21B is schematic cross-sectional view of view of an epitaxial layer structure for an EML of another example embodiment comprising a vertically coupled passive output waveguide;

FIG. 22A is schematic cross-sectional view of view of an epitaxial layer structure for an EML of another example embodiment wherein the laser waveguide is below the EAM waveguide;

FIG. 22B is schematic cross-sectional view of view of an epitaxial layer structure for an EML of another example embodiment wherein the laser waveguide is below the EAM waveguide and comprising monolithically integrated electronics;

FIG. 22C is schematic cross-sectional view of view of an epitaxial layer structure for an EML of another example embodiment wherein the laser waveguide is below the EAM waveguide and comprising monolithically integrated electronics, and comprising a vertically coupled passive output waveguide;

FIG. 23 is a schematic cross-sectional diagram of an epitaxial layer stack for fabrication of a monolithic electro-photonic integrated circuit comprising an EML and driver electronics;

FIG. 24 is a schematic perspective view of a monolithic electro-photonic integrated circuit of an embodiment comprising an EML and driver electronics;

FIG. 25A is a schematic cross-sectional diagram of an example DFB laser diode comprising a MQW i-region;

FIG. 25B is a schematic cross-sectional diagram of an epitaxial layer stack of an example embodiment for a laser diode comprising a MQW i-region;

FIG. 26A is a schematic cross-sectional diagram of an EAM comprising a MQW i-region;

FIG. 26B is a schematic cross-sectional diagram of an epitaxial layer stack of an example embodiment for an EAM comprising a MQW i-region;

FIG. 26C is a schematic diagram to show dimensions of the i-region of a waveguide EAM; and

FIG. 27 is a circuit schematic for a monolithic electro-photonic circuit comprising an EAM and differential driver of an example embodiment, wherein the EAM comprises a parallel resistor.

### DETAILED DESCRIPTION

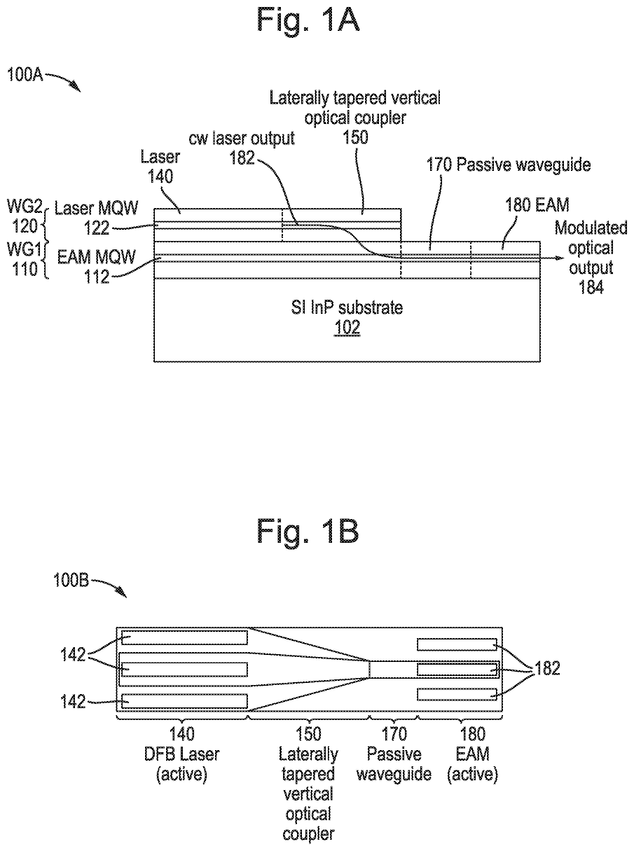

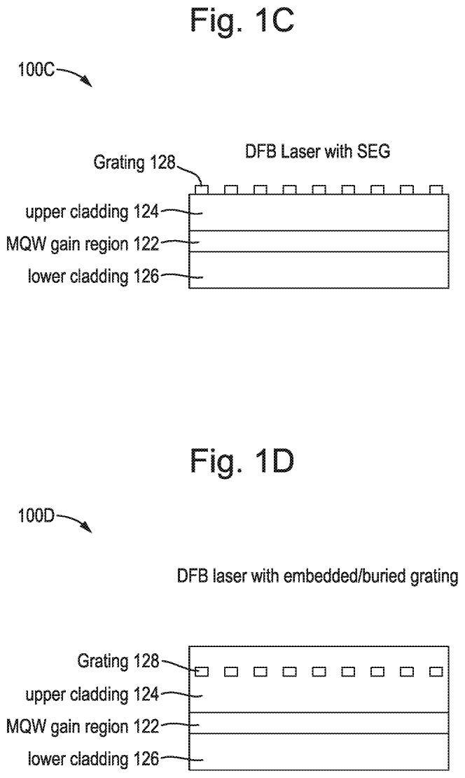

FIG. 1A is a schematic cross-sectional view 100A of a monolithically integrated EML of an example embodiment comprising a laser and EAM fabricated with vertically stacked optical waveguides which are optically coupled by a laterally tapered vertical optical coupler. The EML is fabricated on a semi-insulating (SI) InP substrate 102 and comprises an epitaxial layer stack comprising a plurality of semiconductor layers structured to form a plurality of vertically stacked optical waveguides. In this example there are first and second optical waveguides WG1 110 and WG2 120. The first optical waveguide 110 comprises semiconductor layers structures having a MQW active region (EAM MQW) 112 and upper and lower cladding layers which are structured for operation of part of the first optical waveguide as an EAM 180. The second optical waveguide 120 comprises semiconductor layers having a MQW active region (laser MQW) 122 structured to form a laser diode (laser) 140 and a laterally tapered vertical optical coupler 150. In operation, the CW output of the laser 182 is optically coupled from the laser to the EAM waveguide by the laterally tapered vertical optical coupler 150, and a modulated optical output 184 is provided at the output of the EAM 180. FIG. 1B is a schematic plan view 100B of the EML of FIG. 1A, to illustrate layout of the laser 140, the laterally tapered vertical optical coupler 150 and the active region of the EAM 180, and placement of electrical contacts for the laser and electrical contacts for the active region of the EAM. The first optical waveguide 110 comprises a passive waveguide portion 170 (without electrical contacts) between the taper 150 and the active region of the EAM 180.

The laser 140 in the EML of this embodiment, and EML of other embodiments described herein, may be a distributed feedback (DFB) laser diode comprising a DFB grating structure, e.g. a DFB laser with a surface etched grating (SEG), such as illustrated schematically in FIG. 1C, wherein the laser waveguide comprises a MQW gain region 122, upper and lower cladding layers 124 and 126 and SEG DFB grating 128. The DFB laser may comprise a buried grating 128, such as illustrated schematically in FIG. 1D. In some embodiments, the laser may alternatively be a distributed Bragg reflector (DBR) laser diode, or a Fabry-Pérot laser diode.

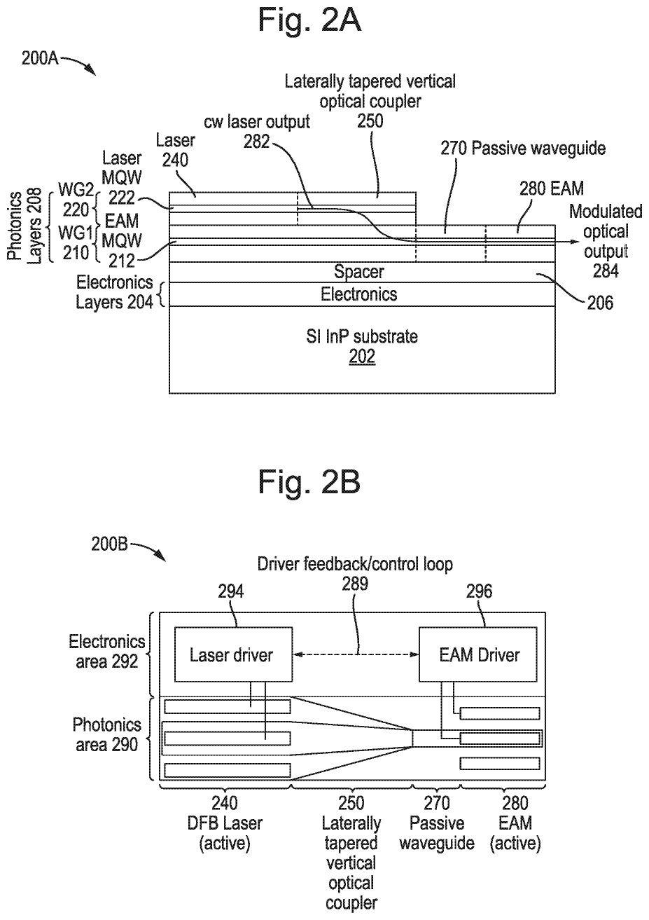

FIG. 2A is a schematic cross-sectional view 200A of a monolithically integrated EML comprising a laser diode (laser) 240 and EAM 280 fabricated with vertically stacked optical waveguides which are coupled by a laterally tapered vertical optical coupler 250, and comprising monolithically integrated electronics layers 204 comprising driver and control electronics. The EML is fabricated on a semi-insulating InP substrate 202 and comprises an epitaxial layer stack comprising a first plurality of semiconductor layers, labelled as electronics layers 204, structured to form electronic circuitry, e.g. comprising InP hetero-junction bipolar transistors (HBT), and a second plurality of semiconductor layers, labelled as photonics layers 208, providing first and second optical waveguides WG1 210 and WG2 220 which are vertically stacked. The first optical waveguide WG1 210 is structured to provide an EAM waveguide comprising a MQW active region (EAM MQW) 212, and the second optical waveguide comprises a MQW active region (laser MQW) 222 structured to provide a laser diode (laser) 240 and a laterally tapered vertical optical coupler 250. A spacer 206 comprising one or more layers separates the electronics layers 204 from the overlying photonics layers 208, and e.g. the spacer comprises one or more layers, e.g. comprising a semi-insulating layer to provide vertical electrical isolation, and an etch stop layer. FIG. 2B is a schematic plan view 200B of the EML of FIG. 2A, to illustrate that the electronics layers comprising a laser driver 294 and an EAM driver 296 are formed on a first area of the substrate 292 and the photonics are formed on a second area 290 of the substrate. One or more metallization layers provide electrical interconnections between the laser driver and the laser and between the EAM driver and the EAM.

As illustrated schematically in FIG. 1C and FIG. 1D, the active gain region or core of the laser diode comprises a MQW structure that forms the active i-region, and the i-region is sandwiched between upper and lower cladding layers to form a p-i-n laser diode.

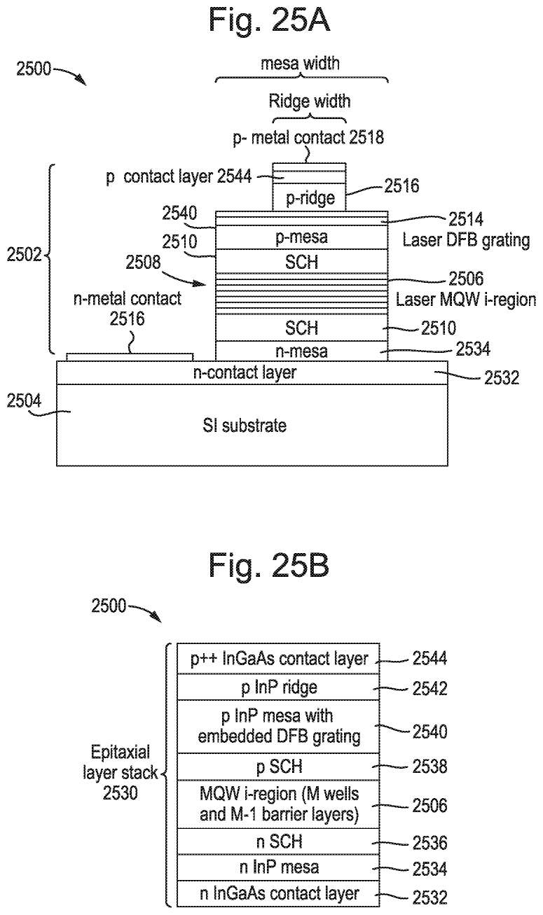

An example laser waveguide structure is illustrated schematically in FIG. 25A and FIG. 25B, for a ridge waveguide laser structure having a p-up configuration. FIG. 25A is a schematic cross-section of a laser waveguide formed on a SI substrate. The laser mesa comprises a MQW i-region comprising a plurality of M wells and M−1 barrier layers, sandwiched between upper and lower separate confinement heterostructures (SCH) , and upper and lower spacer layers of the laser mesa. In this example, a laser DFB grating is formed in the mesa below the ridge. The laser grating may alternatively be provided within the ridge, or be a surface etched grating formed on the ridge. An example epitaxial layer stack for a pin laser diode having a p-up configuration is shown in FIG. 25B. The epitaxial layer structure may alternatively be configured for a n-up configuration. For fabrication of a MQW laser diode for CW operation, the waveguide structure and dimensions are selected to provide a required performance, such as a required output wavelength and mode pattern, output power, slope efficiency (SE) in A/W, threshold voltage et al. The performance of the laser is strongly dependent on the structure of the M QW gain region. The grating may be a uniform grating or a phase shifted grating such as a λ/4 phase shifted grating. For example, a λ/4 phase shifted DFB laser provides high slope efficiency (SE) with high single mode stability. Also, the λ/4 phase shift may in one place or distributed throughout the grating region. The λ/4 phase shift may comprise any one of λ/4 phase, 3λ/4 phase, 3λ/4 phase, etc.

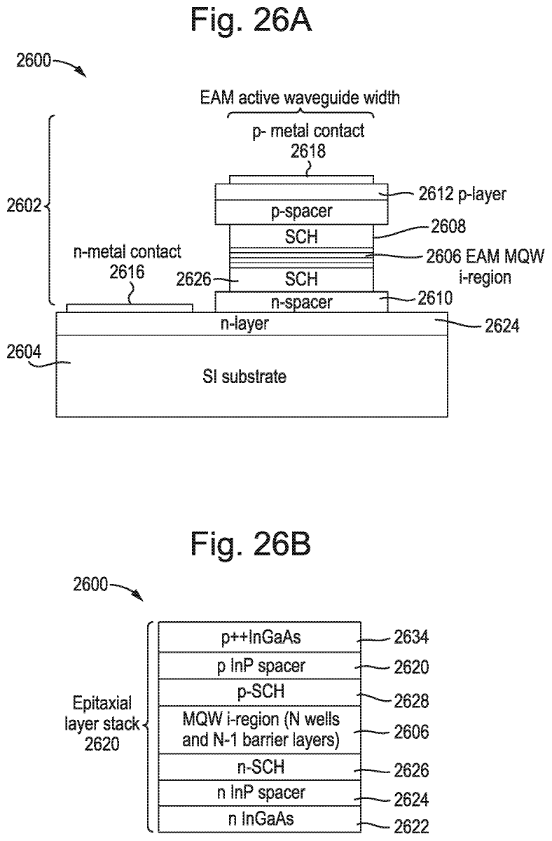

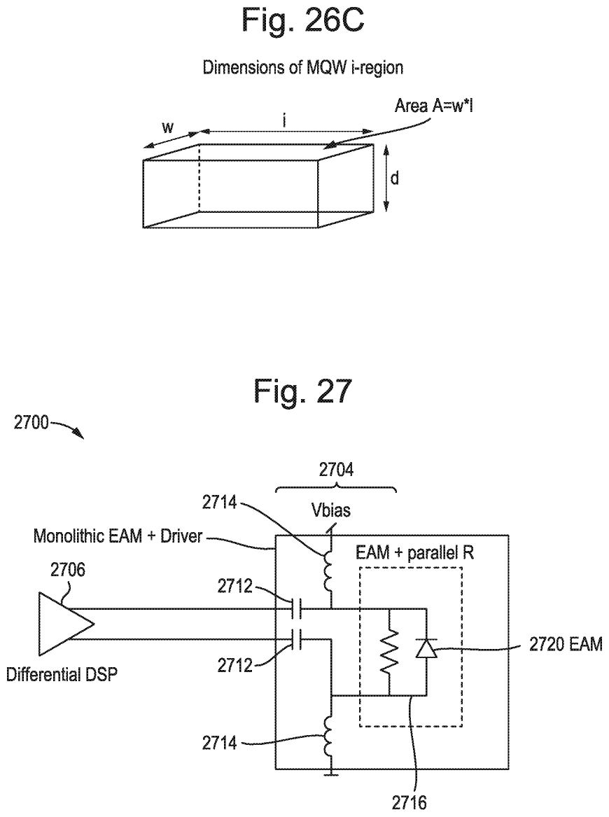

An example waveguide structure for an EAM is illustrated schematically in FIG. 26A, FIG. 26B and FIG. 26C. FIG. 26A is a schematic cross-section of an EAM waveguide formed on a SI substrate. The EAM mesa comprises a MQW i-region comprising a plurality of N wells and N−1 barrier layers, sandwiched between upper and lower separate confinement heterostructures (SCH), and upper and lower spacer layers of the EAM mesa, to form a p-i-n waveguide structure, which in this example has a p-up configuration. An example epitaxial layer stack for an EAM having a p-up configuration is shown in FIG. 26B. The epitaxial layer structure of the EAM may alternatively be configured for a n-up configuration. The EAM waveguide structure and dimensions are selected to provide a required performance, such as a required bandwidth and dynamic extinction ratio (ER), for high-speed modulation, as described for example in the above referenced U.S. patent application no. 63/734,954. For example, the performance of the EAM is strongly dependent on the structure and dimensions of the MQW gain region. Since the EAM device capacitance is dependent on the dimensions of the MQW i-region, i.e. the device area, the device capacitance can be reduced by reducing the width of the MQW active region, relative to the width of the mesa, e.g. by undercutting, as illustrated schematically in FIG. 26A. The length of the MQW active region is selected to be a minimum to provide a required absorption. The MQW structure comprises N wells and N−1 barrier layers where the number N, the well thickness, the barrier thickness, and the ratio of the well thickness to barrier thickness, provide a thickness d of the i-region which provides a required dynamic extinction ratio and which is within a carrier transit time limit of the i-region. The number of wells and barrier layers can be increased to increase the dynamic extinction ratio. Fabrication of an EAM on a semi-insulating substrate reduces device capacitance, and enables use of a differential EAM driver.

The laser waveguide and the EAM waveguide both comprise a MQW active region: the laser MQW structure is the active gain region of the laser and the EAM MQW structure is the active absorption region of EAM. There are constraints on the MQW structures (materials, number of QW, effective refractive index, electrical and optical properties), e.g. to provide a suitable laser gain medium, threshold voltage, spectral efficiency, output power, etc. for laser, and to provide a required bandwidth and dynamic extinction ratio, etc. for the EAM.

For hybrid integration of a discrete laser diode and a discrete EAM, the respective MQWs of the laser diode and the EAM can be optimized independently to adjust their electro-optic properties for required performance parameters.

Based on fabrication and testing of monolithically integrated EML of example embodiments, the applicants have discovered there is a need for solutions that provide improved control of balancing of optical coupling between a laser waveguide and an EAM waveguide based on laterally coupled vertical optical tapers.

For example, a simplified explanation is that if the laser waveguide is strongly guiding relative to the EAM waveguide, not enough light transfers through the taper to the EAM, so the EML is not efficient. If the EAM waveguide is strongly guiding relative to the laser waveguide, light confinement in the laser waveguide is weak, while light confinement is high in the EAM waveguide, which is lossy, which negatively affects the laser mode and laser operation.

Several options to address this problem and provide improved balancing of optical coupling between vertically stacked waveguides comprising a laser waveguide and an EAM waveguide, based on MGVI and laterally coupled vertical optical tapers are disclosed herein. In some aspects, balance of optical coupling can be controlled by the design of the shape of the laterally tapered vertical optical coupler taper, which is one parameter, and/or biasing of part of the laterally tapered vertical optical coupler taper to reduce optical losses, which is another parameter. Another aspect provides a transition waveguide between the laser waveguide and EAM waveguide, a first laterally tapered vertical coupler between the laser waveguide and the transition waveguide, and a second laterally tapered vertical coupler between the transition waveguide and the EAM waveguide, wherein the transition waveguide is a passive, non-absorbing waveguide having an effective refractive index intermediate the effective refractive index of the laser waveguide and the EAM waveguide. However, these aspects may not provide sufficient control of the optical balance between confinement of the optical mode in the laser waveguide and in the EAM waveguide.

There is a need to balance optical coupling between the two waveguides, while maintaining the required electro-optic properties of each waveguide to meet performance requirements. Thus, in another aspect, disclosed herein provides waveguide structures comprising a balancing layer of a material with a refractive index selected to balance optical coupling between the laser waveguide and the EAM waveguide.

For monolithic integration of a laser diode and an EAM using MGVI with laterally tapered vertical optical couplers, e.g. as illustrated schematically in FIG. 1A and FIG. 2A, it is necessary to consider the intensity profiles and effective refractive indices of the myriad of confined modes in this multilayered structure with two waveguiding cores. At the laser end, for efficient lasing at the desired lasing frequency, it is required to have a mode highly confined vertically in the laser core and highly confined laterally within the ridge.

Due to their desired electro-optic characteristics and the constraints of epitaxy, the two guiding cores-principally the laser MQW and the EAM MQW-of these two guiding structures have thicknesses and refractive indices that would tend to be, by themselves close in value. In general, one of the multitude of modes of each polarization will be confined principally in the laser core and will also have a small lobe in the EAM core. We will call this the laser fundamental mode (or ground mode). There will likewise generally be another mode that is principally confined in the EAM core, but having a small lobe in the laser core. We will call this the EAM fundamental mode (or ground mode).

For efficient vertical transfer of the mode from the laser core down to the EAM core via the laterally tapered vertical optical coupler, the laser fundamental mode must have some minimum amount of confinement in the EAM core. It must not, however, have too much confinement in the EAM core, otherwise the round-trip gain of this mode will be reduced. By placing a balancing layer comprising a passive, high refractive index material, such as a layer of quaternary material, near to and above the laser MQW, it is possible to fine tune the confinement of the laser fundamental mode in the EAM core without significantly changing the electro-optic properties of either the laser MQW or the EAM MQW.

The ability to tune the confinement of the laser fundamental mode in the EAM core (and its effective refractive index) by adding a single high refractive index balancing layer of a definite thickness arises from the following. The epitaxial growth process introduces uncertainties in the grown layer thicknesses and compositions. In a complicated multilayer stack of materials these deviations from the values used in calculations (simulations) can conspire to produce a laser fundamental mode that has too much confinement in the EAM core, sometimes even more confinement than it has in the laser mode. The high refractive index balancing layer situated near to and above the laser core provides high refractive index anchoring to ensure that the laser ground mode consistently has a good balance of confinement in the laser and EAM core, that is conducive to both efficient lasing as well as efficient vertical power transfer by the laterally tapered vertical optical coupler.

For the core epitaxial stacks of the laser and the EAM, the effective refractive index difference between the laser fundamental mode and the EAM fundamental mode can serve as a proxy to ensure the lasing fundamental mode has a good balance of confinement factors. The condition is that the lasing fundamental mode should have the highest effective refractive index among the confined modes and the difference between the effective refractive index of the laser fundamental mode and the effective refractive index of the EAM fundamental mode should be in a predetermined range. By way of example, for EML of some example embodiments, the difference between the effective index of the laser fundamental mode and the effective index of the EAM fundamental mode may be selected to be of the order of <0.02.

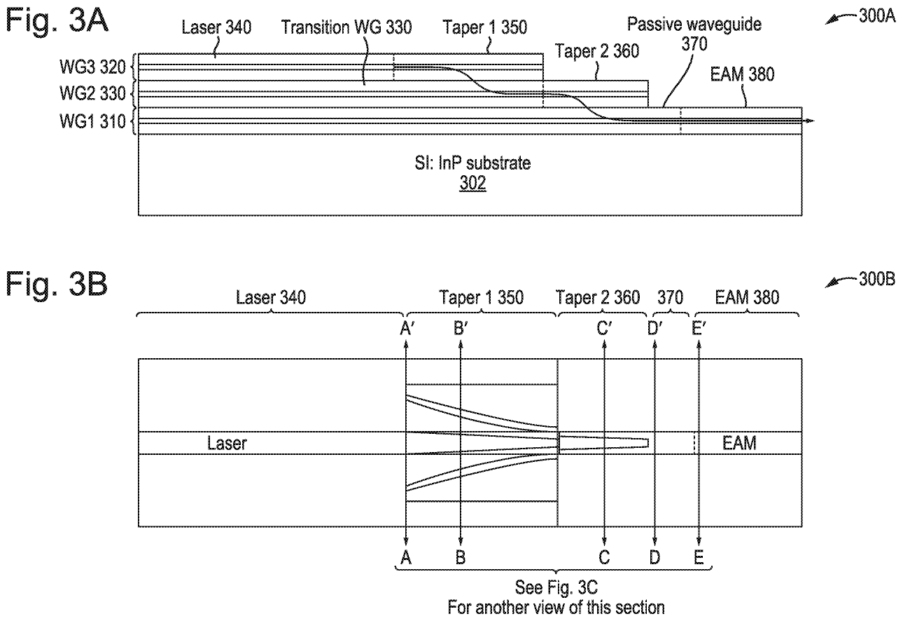

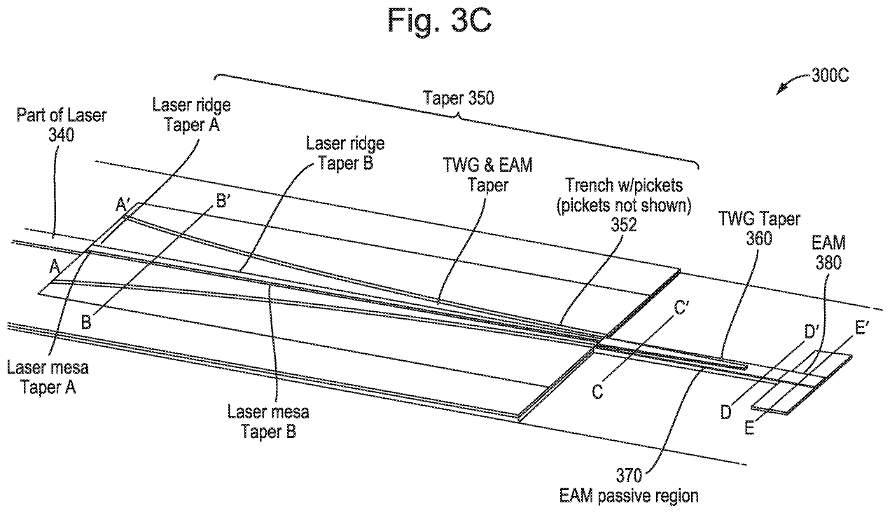

FIG. 3A is a schematic cross-sectional view 300A of an EML of an example embodiment comprising a laser, a transition waveguide, and an EAM, fabricated with vertically stacked optical waveguides which are optically coupled with laterally tapered vertical optical couplers. The EML 300A is fabricated on a semi-insulating InP substrate 302 and comprises an epitaxial layer stack comprising a plurality of semiconductor layers structured to form multiple vertically stacked optical waveguides, in this example first, second and third optical waveguides WG1 310, WG2 330 and WG3 320 are provided. The first optical waveguide 310 comprises semiconductor layers structured as an EAM waveguide having a MQW active i-region. The second optical waveguide 330 comprises semiconductor layers structured to form a passive transition waveguide (TWG). The third optical waveguide 320 comprises semiconductor layers defining a laser waveguide comprising a MQW active i-region, and a first laterally coupled vertical optical coupler. The optical output of the laser is optically coupled from the laser to the transition waveguide by the first laterally tapered vertical optical coupler 350, and the transition waveguide is optically coupled to the EAM waveguide by a second laterally tapered vertical optical coupler 360. FIG. 3B is a schematic plan view 300B of the EML of FIG. 3A, to illustrate placement of the laser 340, the first second laterally tapered vertical optical coupler 350, the second laterally tapered vertical optical coupler 360, passive waveguide 370, and the active region of the EAM 380. By way of example only, in EML of example embodiments, the laser may have a length of 150 μm to 350 μm, the EAM may have a length of 30 μm to 150 μm, and the overall taper length may be 80 μm to 120 μm.

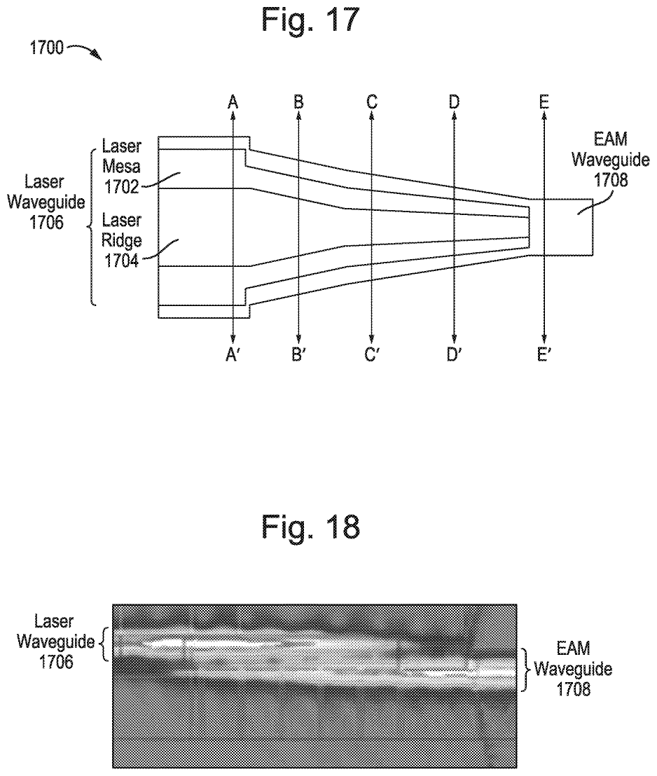

FIG. 3C is schematic perspective view 300C of part of the EML of FIG. 3A and FIG. 3B to illustrate in more detail how the first and second laterally tapered vertical optical couplers 350 and 360 are structured. The first and second laterally tapered vertical optical couplers extend between the optical output of the laser 340 and the optical input of the EAM 380. For the first laterally tapered vertical optical coupler, the laser ridge and laser mesa are etched to define sidewalls of laser ridge taper A and laser mesa taper A, laser ridge taper B and laser mesa taper B. These parts of the taper have a taper shape, or taper profile, designed to transfer the optical mode to the underlying waveguide. A trench 352 is etched through layers of the transition waveguide and EAM waveguide to define sidewalls of the taper 1 350 (as shown in FIG. 3B) of the transition waveguide and EAM waveguide. As illustrated schematically, in the trench has curved sidewalls. For the second laterally tapered vertical optical coupler, taper 2 360 (as shown in FIG. 3B), the layers of the laser waveguide are removed, and the layers of the transition waveguide TWG are etched to define the TWG taper, and the EAM waveguide layers are etched to define a passive waveguide part 370 of the EAM waveguide, and the active region of the EAM 380. By way of example only, lengths of the laser ridge taper A and taper B may be ~20 μm and ~50 μm respectively, the length of the taper of the TWG and EAM waveguides defined by the trench may be ~50 μm; and the second laterally tapered vertical optical coupler may have length of ~25 μm. The tapers have widths that narrows along the length taper, and the sidewalls defining the widths of the tapers may have a curved profile, or a linear profile, a profile comprising a combination of linearly tapered parts (e.g. see FIG. 17), or a profile comprising a combination of curved and linearly tapered portions.

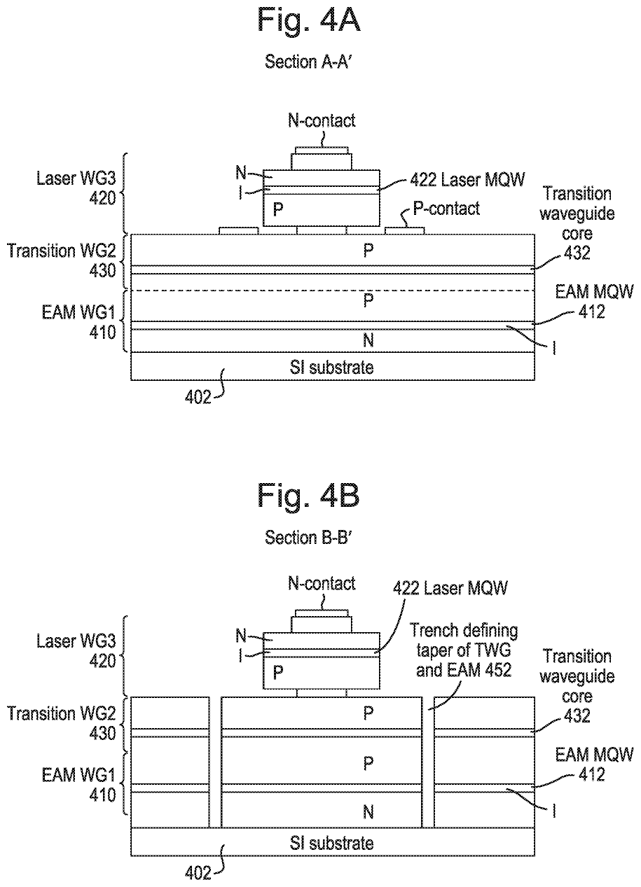

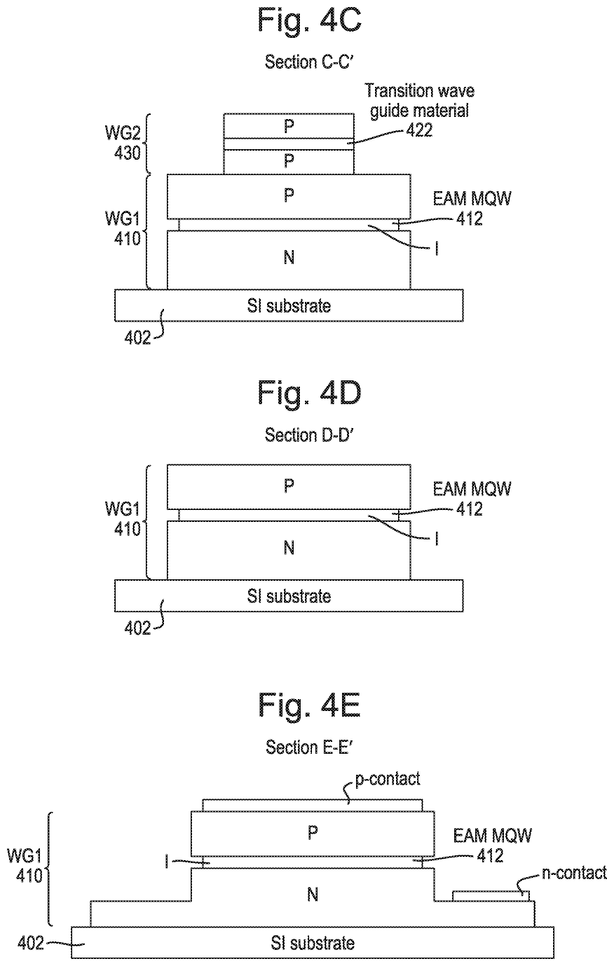

FIGS. 44, 4B, 4C, 4D and 4E are schematic cross-sectional views through sections A-A′ to E-E′ of FIGS. 3B and 3C. FIG. 4A shows a schematic cross-sectional view through section A-A′ comprising the first, second, and third optical waveguides WG1 410, WG2 430, WG3 420, which are structured to provide the laser diode, the transition waveguide and the EAM waveguide, respectively. The laser diode is defined by WG3 and comprises a laser ridge comprising an MQW active i-region, and upper and lower cladding layers which form a p-i-n diode structure of the laser. In this example, the n-cladding and n-contact are on top, and the p-cladding and p-contact are underneath the MWQ active i-region of the laser. For example, the laser ridge is e.g. 2.5 μm to 4.5 μm wide. WG2 is a passive transition waveguide, comprising p-spacer layers and the core of the transition waveguide comprises a material, which is non-absorbing (transparent). WG1 comprises an EAM waveguide having MQW active i-region, and upper and lower cladding layers. In this example, the p-cladding is on top, and the n-cladding is underneath the EAM MQW active i-region. If the EML is fabricated with an InP-based material system, the core of the transition waveguide, which is non-absorbing, may be e.g. InGaAsAl or InGaAsP. FIG. 4B shows a schematic cross-sectional view through section B-B′, to show the trench 452 etched through the transition waveguide layers and the EAM waveguide layers to define sidewalls of the first laterally tapered vertical optical coupler. FIG. 4C shows a schematic cross-sectional view through section C-C′, through the second laterally coupled vertical optical coupler, comprising a tapered part of the transition waveguide and the underlying EAM waveguide. As illustrated schematically, the EAM MQW i-region may be undercut. FIG. 4D shows a schematic cross-sectional view through section D-D′, through the second laterally coupled vertical optical coupler, and a tapered part of EAM waveguide where the overlying transition waveguide has been removed. This portion of the EAM waveguide forms a passive waveguide between the end of the taper and the active region of the EAM. FIG. 4E shows a schematic cross-sectional view through section E-E′, through the active region of the EAM waveguide, comprising the EAM MQW i-region, which is sandwiched between p-layer and n-layers, and electrical connections comprising a p-contact and n-contact for driving the EAM. As illustrated schematically, the MQW region of the EAM is undercut, so that the width of the EAM MQW i-region is made narrower relative to the ridge width of the EAM, e.g. to reduce device capacitance.

The laser layers are absorptive where they are not forward biased. The EAM top p-contact must be placed vertically a certain distance away from the bottom of the laser MQWs to allow the side injected holes sufficient runway to diffuse to a laterally uniform profile when they reach the laser MQWs. The design rational is to place a passive transition waveguide (TWG) vertically near the laser MQWs, configured to quickly move the laser light down into the transition waveguide where it can travel without being absorbed, and then to move the light down to the MQW i-region of the EAM waveguide. In practice, this three-waveguide structure is quite sensitive to the effective refractive index of each waveguide To achieve vertical optical coupling between the laser mode, through the transition waveguide, to the EAM waveguide, the effective refractive index of each waveguide must be carefully selected to balance optical coupling. For example, if the EML is fabricated with an InP-based materials system, and if the transition waveguide material, which is non-absorbing, is a material such as InGaAIAs or InGaAsP, having a refractive index of e.g. n=3.4, the effective refractive index of the laser waveguide comprising the laser M QW region is selected to be in a range n+Δn, higher than the effective refractive index of the transition waveguide, and the effective refractive index of the EAM M QW region is selected to be in a range of n−Δn, lower than the effective refractive index of the transition waveguide. To balance optical coupling between the laser waveguide and the EAM waveguide through the transition waveguide requires tight control of the effective refractive index of the laser MQW, the transition waveguide material, and the EAM MQW. For example, if the difference in the effective refractive index difference between waveguides Δn is too great, the optical mode may remain strongly confined in the laser waveguide, and fail to be vertically coupled to the underlying waveguides, or conversely if the optical mode is too strongly confined in the EAM waveguide, it will negatively affect operation of the laser. Strict control of the effective refractive index differential between the transition waveguide and the laser waveguide and between the transition waveguide and the EAM waveguide is required to control confinement of the optical mode in the laser waveguide and in the EAM waveguide. The sensitivity to refractive index variations may present a challenge for manufacturing unless fabrication process tolerances from foundry-to-foundry or batch-to-batch are controlled within a prescribed range.

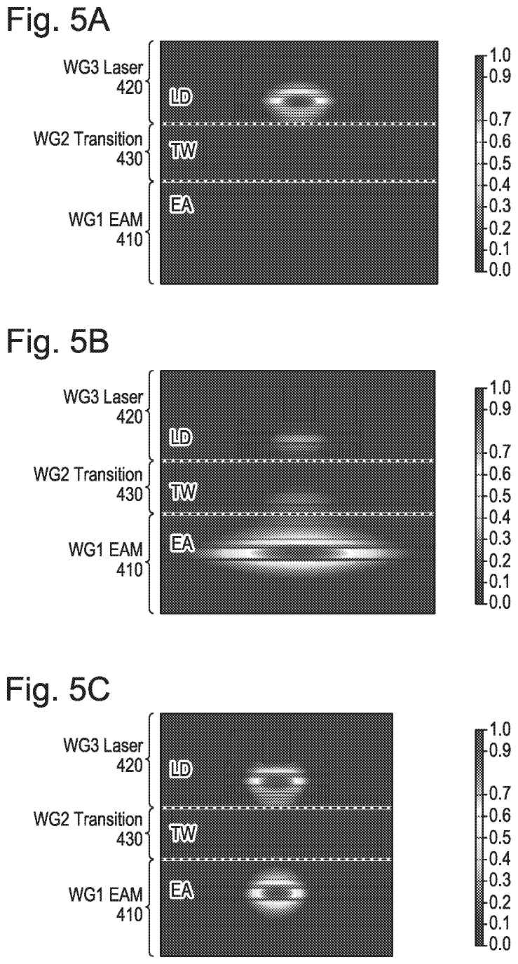

FIGS. 5A to 5C show some example optical mode patterns. FIG. 5A is a diagram created by optical modelling of an optical mode pattern within an EML comprising a laser waveguide and an EAM waveguide structure, such as those illustrated in FIGS. 4A to 4E, wherein the optical mode is confined laterally and vertically within the laser waveguide. FIG. 5B is a diagram created by optical modelling of an optical mode pattern within the laser waveguide and the EAM waveguide, to illustrate vertical transition of the optical mode from the laser waveguide to the EAM waveguide, wherein the optical mode is mostly vertically confined within the EAM waveguide. In this example, the mode in the EAM is without lateral confinement, and spreads laterally. FIG. 5C is a diagram created by optical modelling of an optical mode pattern within the laser waveguide and the EAM waveguide of FIGS. 4A to 4E, showing distribution of the optical mode between the laser waveguide and the EAM waveguide, where the optical mode is split between the laser waveguide and the EAM waveguide. In this example, light is split so that the optical mode is laterally and vertically confined in the laser waveguide, and is vertically and laterally confined within the EAM waveguide. The scale in FIG. 5C shows relative intensity of the mode pattern.

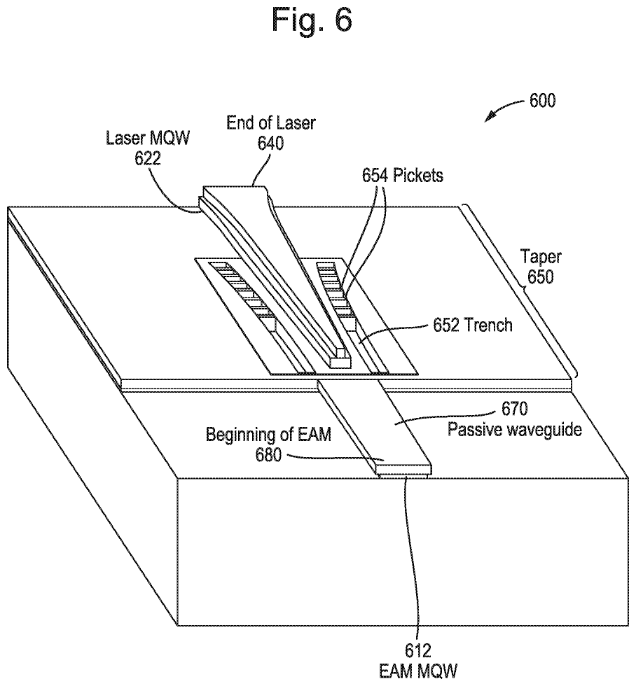

FIG. 6 is a schematic perspective view of part of an EML of another example embodiment, such as those shown in FIGS. 1A and 1B and FIGS. 2A and 2B, wherein the EML comprises two vertically stacked optical waveguides, the first optical waveguide comprising an EAM waveguide and the second optical waveguide comprising a laser waveguide. The output of the laser diode is coupled to the input of the active region of EAM by a laterally tapered vertical optical coupler 650 and a part of the EAM waveguide which is a passive waveguide 670. FIG. 6 shows more details of the structure of the laterally tapered vertical optical coupler between the laser and the EAM. Optical modelling for the EML structure of embodiments such as those shown in FIG. 6, wherein the laser mode is coupled through the laterally tapered vertical optical coupler into the EAM waveguide (without an intermediate transition waveguide) is significantly more tolerant to variations in refractive indices for the EAM waveguide and the laser waveguide. For example, during fabrication, there may be foundry-to-foundry or batch-to-batch process variations, which affect the refractive indices of the epitaxial layers of the EAM waveguide and laser waveguide. However, if the difference in effective refractive index between the laser waveguide and the EAM waveguide is maintained within an acceptable range, which will of course depend on the particular materials and structure of each waveguide, and fabrication processes, an appropriate balance between the optical mode in the laser waveguide and the EAM waveguide can be achieved.

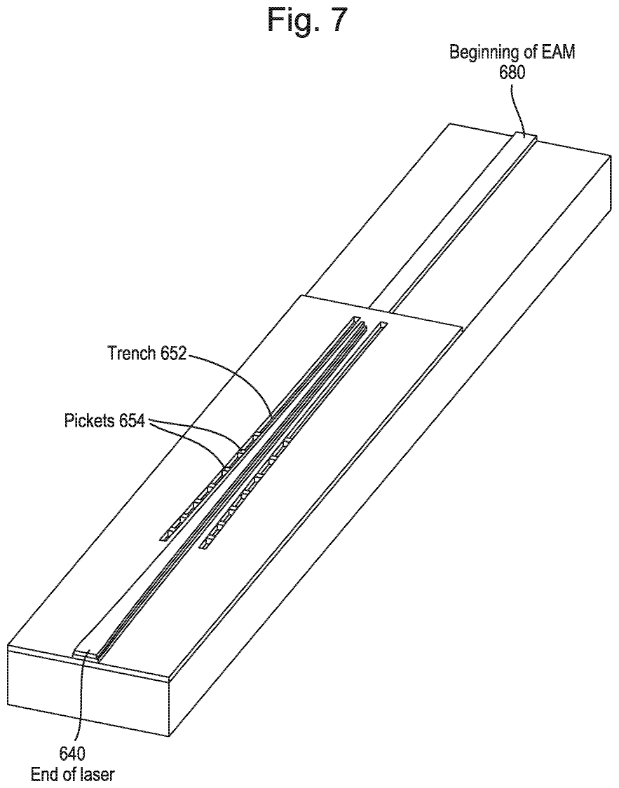

FIG. 7 is another schematic perspective view of part of the EML of FIG. 6 Layers of the second optical waveguide WG2, comprising layers forming the laser ridge and laser mesa are etched through to define tapered sidewalls of the laser ridge and laser mesa. A trench 652 is etched through the layers forming the first optical waveguide WG1 of the EAM to form tapered sidewalls of the EAM layers which provide lateral confinement of the optical mode as it transitions through the lateral taper into the EAM waveguide and is coupled to the input of the active region of the EAM. As illustrated in FIGS. 6 and 7, the trenches each side of the EAM may not be continuous; there may be bridges across part of the length of each trench. The bridges carry metal interconnect traces between top contact metal of the EAM and the tapered region of the laser mesa and laser ridge, to enable this part of the taper to be energized. To avoid absorption losses in the taper, the taper is biased to transparency. The bias may diminish along the taper. The metal interconnect traces form what are referred to as pickets 654, along sidewalls of the tapered layers, which act to provide lateral confinement of the optical mode as it transitions from the taper of the laser waveguide into the underlying EAM waveguide.

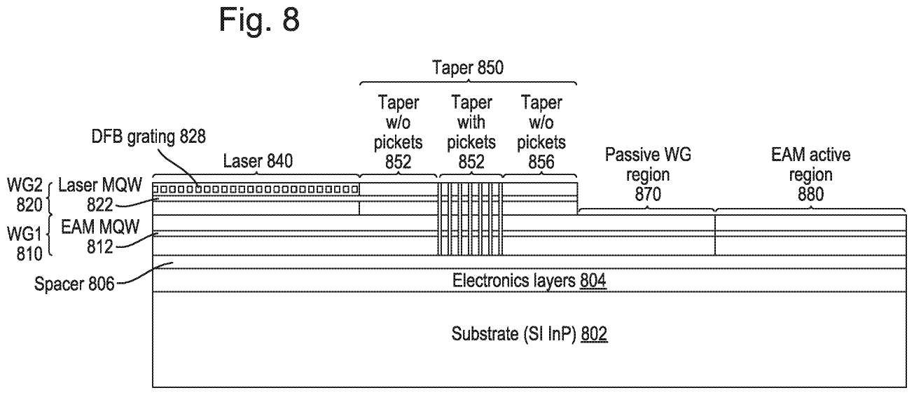

FIG. 8 is a schematic cross-sectional view of as EML of an embodiment similar to that shown in part in FIGS. 6 and 7, and comprising monolithically integrated electronics. The EML is fabricated from an epitaxial layer structure comprising a plurality of semiconductor layers formed on a semi-insulating (SI) substrate 802. For example, the SI substrate comprises SI InP, and the EML is fabricated from an In-P based materials system comprising selected binary, ternary, quaternary and other compositions of In, Ga, As, Al, P and Sb. These compositions are selected to be lattice matched to InP or nearly lattice matched to InP. A first plurality of semiconductor layers is structured to provide electronics layers 804, e.g. comprising InP HBTs for an EAM driver and any other electronics, e.g. for control and monitoring and a laser driver. A spacer 806 comprising one of more layers separates the electronics layers from a second plurality of semiconductor layers. The second plurality of semiconductor layers are photonics layers structured to provide a plurality of vertically stacked optical waveguides. In this embodiment a first optical waveguide WG1 810 is structured to form an EAM waveguide and a second optical waveguide WG2 820 is structured to define a waveguide of a laser diode 840 and a laterally tapered vertical optical coupler 850. The EAM waveguide has a MQW i-region 812, sandwiched between upper and lower cladding layers to form a pin waveguide structure. The laser waveguide defines a laser diode having a MQW i-region 822 sandwiched between upper and lower cladding layers to form a pin-laser diode. In this embodiment, the laser diode is a DFB laser diode having a DFB grating 818, which may be a buried grating, or a surface etched grating. Part of the laser waveguide defines a laterally tapered vertical optical coupler 850 which extends from an optical output of the laser diode. Along the length of the taper, layers of the laser ridge and laser mesa are etched to define sidewalls of the taper, e.g. as illustrated schematically for the EML of embodiments shown in FIG. 6 and FIG. 7. In a first part of the taper, the layers of the laser waveguide 820 are etched and the layers of the EAM waveguide are not etched. A trench is etched through a second part of the layers of the EAM waveguide to define sidewalls of a lateral taper through the EAM waveguide layers. Part of the trench is not continuous and comprises bridges of material which support metal traces, referred to as pickets because they resemble a picket fence, which extend along sidewalls of the taper as illustrated schematically in FIG. 6 and FIG. 7. The pickets provide bridges for electrical interconnect traces that allow the taper to be biased to reduce optical absorption losses, and the pickets assist in providing lateral optical confinement of the optical mode in the tapered portion of the EAM waveguide. The optical mode transitions from the end of the taper into a passive part 870 the EAM waveguide, which is laterally coupled to an active region 880 of the EAM waveguide. The active region of the EAM comprises a p-contact and a n-contact for driving the EAM. One or more metallization layers provide electrical interconnections, e.g. electrical connections between the EAM driver and the active EAM waveguide. Electrical interconnections are provided by one of more metallization layers and intermetal dielectric layers of compatible materials.

By way of example, the laser diode may have a length in a range of e.g. 150 μm to 350 μm. The taper may have a length in a range of e.g. 80 μm to 100 μm. As illustrated schematically in FIG. 6 and FIG. 7, the taper may comprise a first part of the taper wherein only layers of the laser waveguide are tapered, and second and third parts defined by the trench, wherein EAM waveguide layers are tapered within the trench; for example the second part comprises pickets, and the third part is without pickets. The passive waveguide region of the EAM waveguide extends from the end of the taper to the EAM active region, and may have a length of e.g. ~20 μm. The EAM active region may have a length in a range of, e.g. 30 μm to 150 μm.

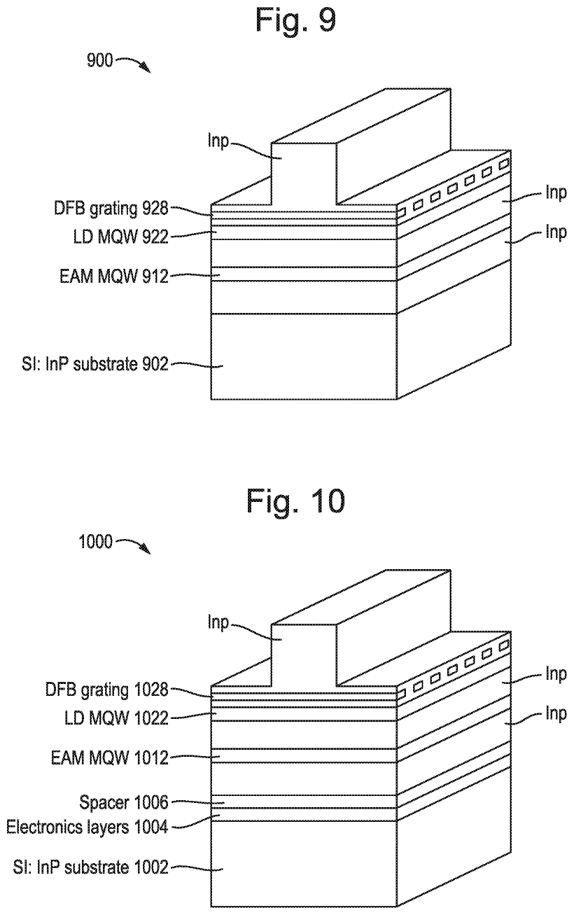

FIG. 9 shows a schematic perspective view of part of an EML 900 of an embodiment comprising a laser waveguide for a DFB laser comprising a laser MQW 922, and an EAM waveguide comprising an EAM MQW 912, fabricated on a SI InP-substrate 902, and comprising InP-based materials. The DFB grating 928 is fabricated from a quaternary layer (Q-material). In this embodiment, the DFB grating 928 is positioned below the ridge of the laser waveguide.

FIG. 10 shows a schematic perspective view of part of an EML 1000 of an embodiment comprising a laser waveguide comprising a laser MQW 1012 for a DFB laser having a buried grating 1028, e.g. comprising a Q-material) and an EAM waveguide comprising an EAM MQW 1012, fabricated on a SI InP substrate 1002, similar to that shown in FIG. 9, and comprising integrated electronics layers 1004. The electronics layers 1004 are separated from the photonics layers by a spacer 1006.

For example, the EML of FIGS. 1A and 1B may be implemented with the structure shown in FIG. 9. For example, the EML of FIGS. 2A and 2B may be implemented with the structure shown in FIG. 10. In these device structure, it is not possible to control independently optical coupling to the laser grating and mode extension to the EAM. There is a trade-off in performance between DFB coupling coefficient k and the ability to taper to the EAM. Strong coupling to the EAM may result in laser mode loss. There is a need for balancing the optical confinement in the laser waveguide and in the EAM waveguide, while maintaining the DFB coupling coefficient k in an appropriate range.

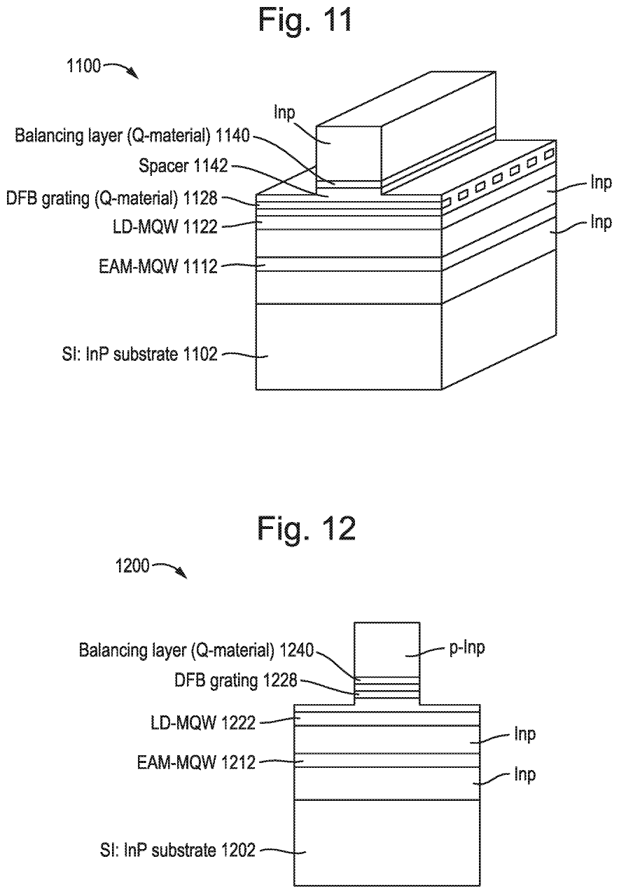

FIG. 11 is schematic perspective view of part of an EML 1100 of an example embodiment, wherein the epitaxial layer stack comprises an SI substrate 1102, and EAM waveguide comprises an EAM MQW 1112, a laser waveguide comprising a Laser MQW 1122, and a DFB grating 1128, which may comprise a Q-material. The epitaxial layer stack is similar to that shown in FIG. 10. Additionally, the layers for the DFB laser comprise a “balancing layer” 1140 inserted in the laser ridge, above the DFB grating 1128. The balancing layer is a layer of a material having a higher refractive index relative to InP, for example a balancing layer of a quaternary material (Q-material), such as InGaAsP or AlGaInAs material, having a higher refractive index compared to InP. By choosing a proper thickness and composition of the balancing layer, a low threshold voltage, and higher power laser performance can be achieved as well as efficient optical transfer from the laser waveguide to the EAM waveguide. The balancing layer of Q-material is provided to control the DFB coupling coefficient k and the optical mode distribution between the DFB laser and the EAM. The balancing layer of Q-material provides for more flexibility in the design of the laterally tapered optical coupler, e.g. to achieve weak tail coupling to minimize laser mode loss.

The balancing layer of Q-material may be positioned above the laser MQW within the ridge above or below the grating. The balancing layer may be undercut relative to the ridge.

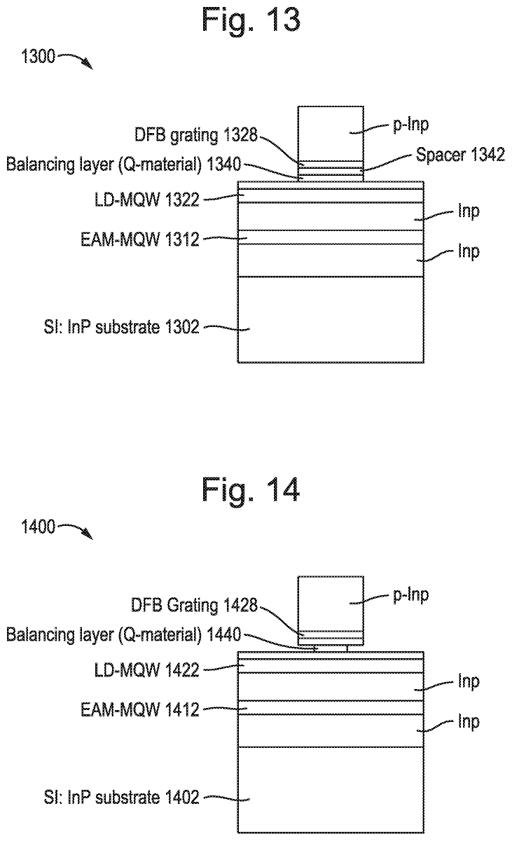

For example, FIG. 12 is schematic cross-sectional view an EML 1200 of an embodiment wherein a DFB laser comprises a DFB grating 1228 within the ridge and the balancing layer 1240 is inserted in the ridge, above the DFB grating 1228. FIG. 13 is schematic cross-sectional view of an EML of an embodiment wherein a DFB laser comprises a DFB grating 1318 within ridge and the balancing layer 1340 is inserted in ridge, below the DFB grating 1318.

FIG. 14 is schematic cross-sectional view of part of an EML 1400 of an embodiment wherein the DFB laser comprises a DFB grating 1428 is within ridge, a balancing layer 1440 is inserted in ridge, below the DFB grating 1428, and the balancing layer is undercut, so its width is less than the width of the laser ridge. This structure is applicable to embodiments where there is down tapering of layers of the laser waveguide, where the mode initially sitting within the laser waveguide is squeezed down into the modulator waveguide.

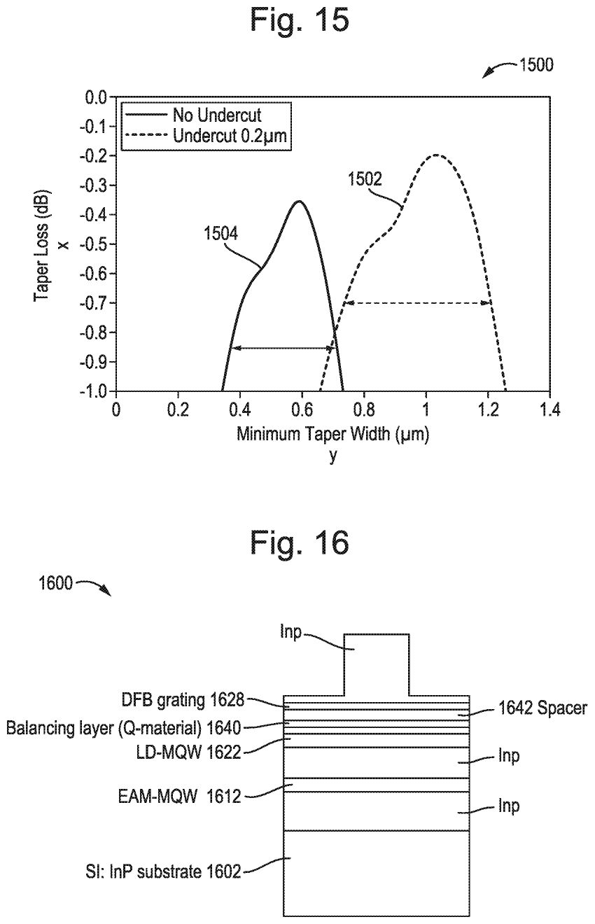

FIG. 15 is a plot showing taper loss (dB) vs. taper width for example embodiments, with and without undercut of the balancing layer. The design with undercut of the balancing layer has some advantages. For example the balancing layer is wet-etched to provide the undercut. The taper loss is lower with the undercut, and the minimum taper width and 0.5 dB width tolerance of the taper are improved for the structure which is undercut. The balancing layer provides relaxed fabrication tolerances for the width of the taper in terms of photolithography critical dimensions of the laser ridge and mesa. This advantage is provided by the balancing layer controlling balance between portions of light confined within the cores of WG1 and WG2. The relaxed fabrication tolerances are achieved by utilizing a well-controlled wet-etch time to provide predetermined lateral dimension of the wet etch undercut. This structure therefore provides improved design tolerances, and is more robust for fabrication.

FIG. 16 is schematic cross-sectional view of part of an EML 1600 of an embodiment wherein the DFB laser comprises a DFB grating 1628 within the mesa and a balancing layer 1640 is inserted in mesa, below the DFB grating 1628. In another embodiment, not illustrated, the balancing layer 1640 may be inserted in the mesa above the DFB grating 1628.

By way of example, the balancing layer of Q-material may have a thickness in a range of e.g. 80 nm to 100 nm, and the spacer layer may have a thickness in a range of e.g. 50 nm to 70 nm. An appropriate thickness of the balancing layer 1640 of Q-material to adjust or tune the effective refractive index of the laser waveguide may be determined by optical modelling, and verified by experimental testing of test structures using various thicknesses of the balancing layer of Q material and spacer layer. In the foregoing examples, a balancing layer comprising a layer of Q material is discussed. Alternatively, the balancing layer may comprise a layer of another composition that has an appropriate refractive index and is lattice-matched, or nearly lattice-matched to avoid Matthew-Blakeslee dislocations within the crystal lattice.

FIG. 17 is a schematic diagram of part of an EML comprising a laterally tapered vertical optical coupler of an example embodiment. FIG. 18 is a schematic vertical cross-section through the taper of FIG. 17 illustrate how the optical mode transitions from the laser waveguide to the EAM waveguide over the length of the taper.

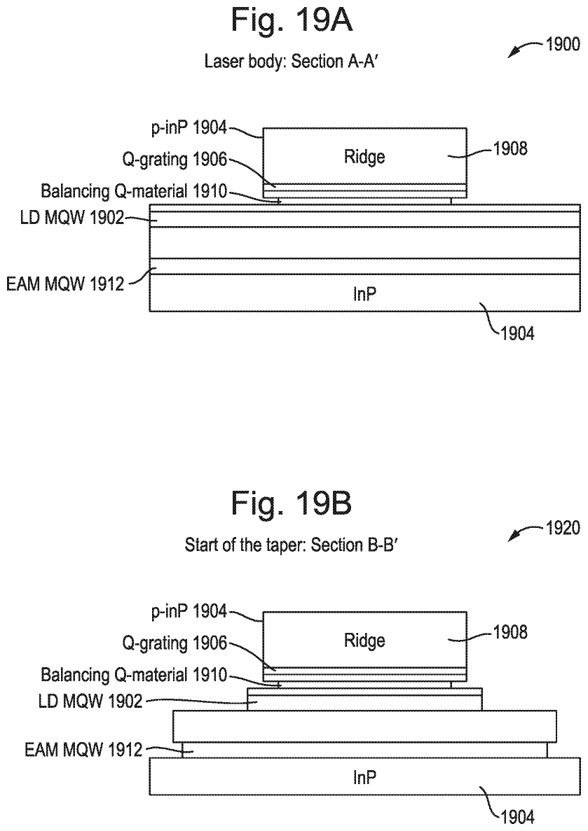

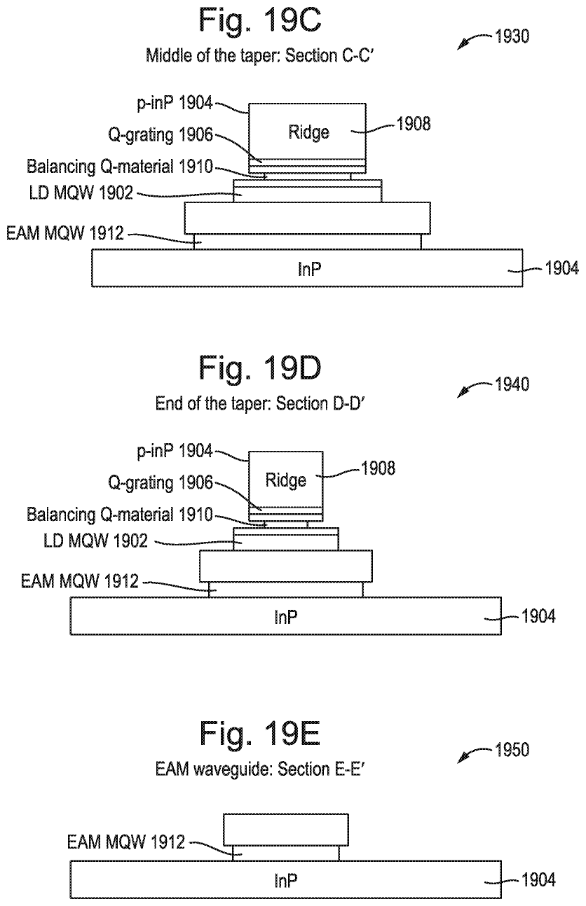

FIGS. 19A to 19E are schematic cross-sectional views through sections A-A′ to E-E′ of an EML of another example embodiment, comprising a taper as illustrated in FIG. 17. These cross-sectional views are through the waveguide layers only, and the SI substrate and any electronics layers are not illustrated in these views.

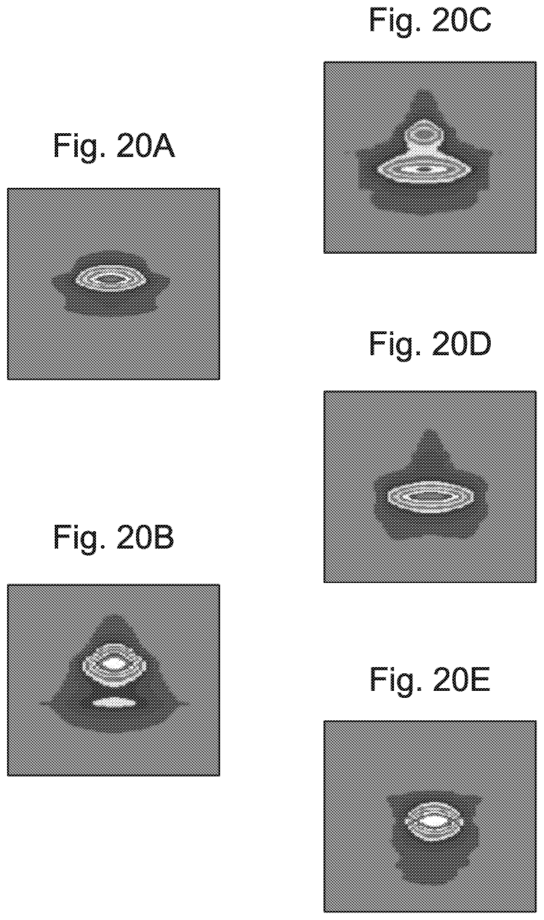

FIGS. 20A to 20E are schematic cross-sectional views through sections A-A′ to E-E′ of FIG. 19A to 19E showing the optical mode shapes at each cross-section, created by optical modelling.

FIG. 19A shows a schematic cross-sectional view through section A-A′ including the laser body. The laser diode comprises a laser mesa and laser ridge defined by WG2 and comprising an MQW active i-region (LD-MQW), and upper and lower cladding layers of InP which form a p-i-n diode structure of the laser. In this example, the p-cladding and p-contact are on top and the n-cladding and n-contact are underneath the MWQ active i-region of the laser. A DFB grating of Q-material is defined within the ridge. A balancing layer of Q material is provided underneath the grating, and separated therefrom by a spacer layer. For example, the laser ridge is 2.5 μm to 4.5 μm wide, and the balancing layer is undercut to form a narrow neck above the LD-MQW i-region of the laser. WG1 comprises an EAM waveguide having MQW active i-region, and upper and lower cladding layers of InP. In this example, the n-cladding is on top and the p-cladding is underneath the EAM-MQW active i-region. In the laser body, the ridge is wide enough that the laser mode is laterally confined by the ridge width and is sitting in the laser mesa, only slightly penetrating into the EAM waveguide, as illustrated in FIG. 20A. FIG. 19B shows a schematic cross-sectional view through section B-B′ which is the start of the taper. As the ridge and the mesa of the laser waveguide narrow, the optical mode starts to transfer into the EAM waveguide, as illustrated by the optical mode pattern in FIG. 20B. FIG. 19C shows a schematic cross-sectional view through section C-C′, through the middle of the taper where the taper has narrowed so that the optical mode is distributed between the laser mesa and the EAM core, as illustrated by the optical mode pattern in FIG. 20C. FIG. 9D shows a schematic cross-sectional view through section D-D′, close to the end of the taper, where the optical mode is mostly within passive region of the EAM waveguide, as illustrated by the optical mode pattern in FIG. 20D. FIG. 19E shows a schematic cross-sectional view through section E-E′, through the active region of the EAM waveguide, which is sandwiched between p-layer and n-layers, and comprising a p-contact and n-contact for driving the EAM. As illustrated by the mode pattern in FIG. 20E, the optical mode is within the EAM MQW i-region. The width of the EAM MQW i-region is made narrower by an undercut, to reduce device capacitance.

As illustrated schematically in FIGS. 19A and 20A, in the laser body, the optical mode is laterally and vertically confined in the core of the laser waveguide comprising the laser MQW. As illustrated schematically in FIGS. 19E and 20E, in the EAM, the optical mode is vertically and laterally confined within core of the EAM waveguide comprising the EAM MQW. The balancing layer is provided with the laser waveguide above the laser MQW i-region, and has a refractive index selected to balance optical coupling and provide high confinement of the optical mode within the core of the laser, and lower confinement of said optical mode within the core of the EAM. The design of the taper provides for transition of light from the laser core to the EAM core along the length of the taper.

In EML of example embodiments, the balancing layer allows for efficient control of laser parameters such as mode confinement and distributed feedback coupling to deliver superior laser operation. The balancing layer also facilitates optical mode transfer from the DFB laser waveguide to the EAM waveguide within relaxed fabrication tolerances.

Optical modelling for the EML structure of embodiments wherein the laser mode is coupled through the laterally tapered vertical optical coupler into the EAM waveguide, without a transition waveguide is significantly more tolerant to variations in effective refractive indexes for the EAM waveguide and the laser waveguide. For example, during fabrication, there may be foundry-to-foundry and batch-to-batch process variations of material structure and properties such as refractive index of various layers of the epitaxial layer structure. However, as long as the difference in effective refractive index between the laser waveguide and the EAM waveguide is maintained within an acceptable range, an appropriate balance between confinement of the mode in the laser waveguide and confinement of the mode in the EAM waveguide can be achieved. The required difference in effective refractive index will depend on the specific materials and structure of each waveguide. For example, for EML of example embodiments comprising waveguides based on an InP-based material system, and the balancing layer is a layer of a material having a refractive index higher than InP, the difference in effective refractive index between the laser waveguide and the EAM waveguide may be of the order of e.g. ≥0.02.

It is also contemplated that the effective refractive index of the EAM waveguide may be adjusted or tuned by adding a balancing layer to the EAM waveguide structure. For example, the EAM waveguide may have a balancing layer of a lower refractive index to reduce the effective refractive index of the EAM waveguide relative to the effective refractive index of the laser waveguide, to provide a required difference in effective refractive index of the laser waveguide and the EAM waveguide.

A balancing layer as described herein is one example of a manner in which the difference in the effective refractive index of the laser waveguide and of the EAM waveguide can be adjusted, to balance confinement of the optical mode between the laser waveguide and the EAM waveguide, and the skilled person will be aware of other equivalent manners of achieving this function or effect.

In EML of example embodiments, the laser may be a DFB laser with a surface etched grating, a DFB laser with a buried or embedded grating (may be referred to as a floating grating). In other embodiments, the laser may be another suitable type of semiconductor laser, such as a Distributed Bragg Reflector (DBR) laser or a Fabry-Pérot (FP) laser, which is coupled to an EAM waveguide with a laterally tapered vertical optical coupler.

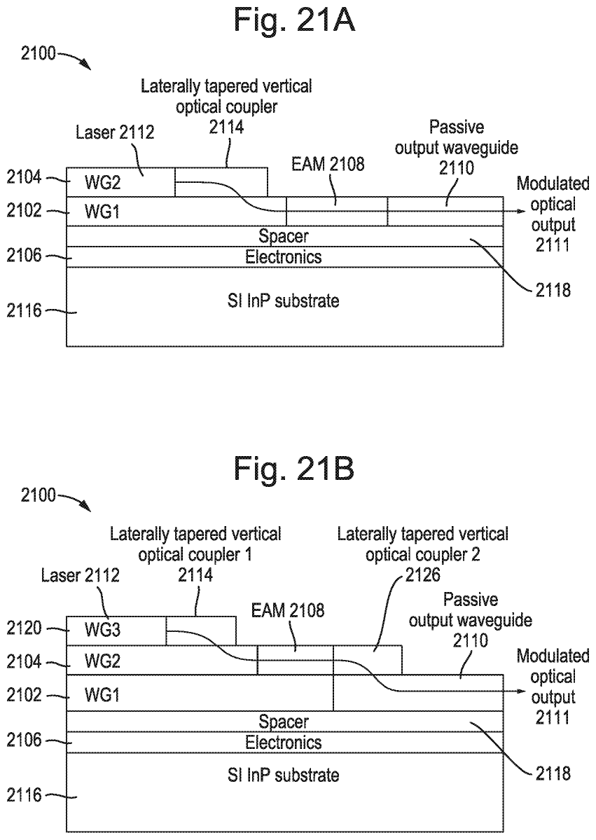

FIG. 21A is a schematic cross-sectional view of a monolithic EML of an embodiment comprising first and second vertically stacked optical waveguides WG1 and WG2, and integrated electronics, and wherein the output of the EAM is laterally coupled to a passive output waveguide. FIG. 21B is a schematic cross-sectional view of a monolithic EML of an embodiment comprising first, second and third vertically stacked optical waveguides WG1, WG2 and WG3, and integrated electronics. WG3 defines a laser and a first laterally tapered vertical optical coupler (taper1); WG2 defined a passive waveguide, an active EAM region, and a second laterally tapered vertical optical coupler (taper 2); and WG1 is a passive output waveguide. The output of the laser is coupled to the EAM through taper 1 and the output of the EAM is coupled to the passive output waveguide by taper 2. The passive output waveguide may comprise a spot size converter (SSC). The passive output waveguide may comprise a multiplexer.

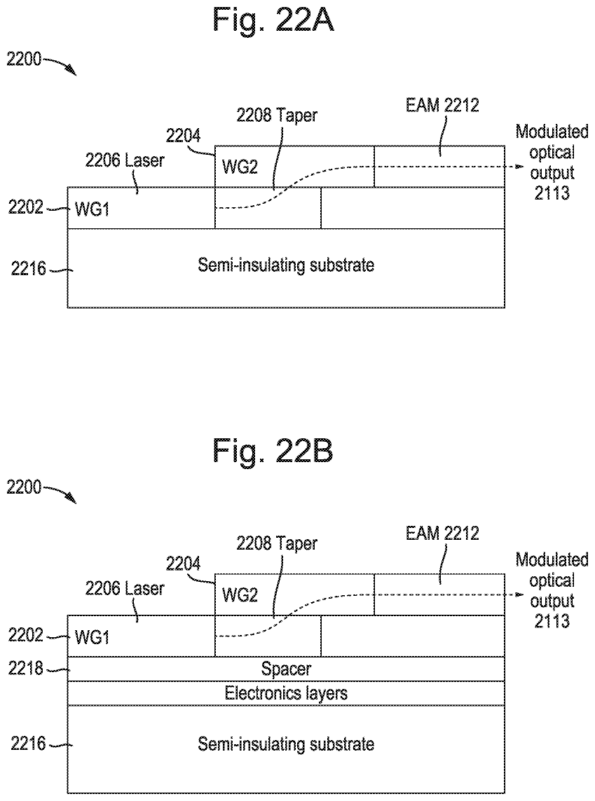

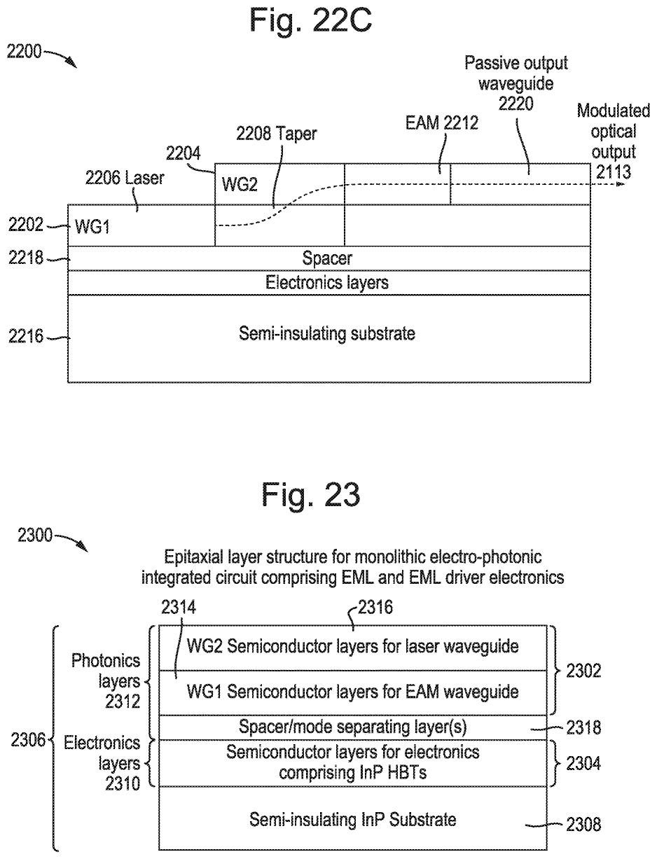

FIG. 22A is a schematic cross-sectional view of a monolithic EML of an embodiment comprising first and second vertically stacked optical waveguides WG1 and WG2, where WG1 defines a laser and a laterally tapered vertical optical coupler (taper) and WG2 defines a passive waveguide and an active EAM region, the output of the laser being coupled through the taper to the passive waveguide and into the EAM active region. FIG. 22B is a schematic cross-sectional view of a monolithic EML of an embodiment comprising first and second vertically stacked optical waveguides WG1 and WG2, where WG1 defines a laser and a laterally tapered vertical optical coupler (taper) and WG2 defines a passive waveguide and an active EAM region, the output of the laser being coupled through the taper to the passive waveguide and into the EAM active region, and comprising integrated electronics. FIG. 22C is a schematic cross-sectional view of a monolithic EML comprising first and second vertically stacked optical waveguides WG1 and WG2, where WG1 defines a laser and a laterally tapered vertical optical coupler (taper) and WG2 defines a passive waveguide, an active EAM region, and a passive output waveguide, and integrated electronics. The output of the laser is coupled through the taper to the passive waveguide and into the EAM active region, and the output of the EAM is laterally coupled to the passive output waveguide.

FIG. 23 shows an example epitaxial layer structure for fabrication of a monolithic electro-photonic integrated circuit comprising an EML and EML driver electronics. The epitaxial layer stack is grown on a semi-insulating substrate, and comprises a first plurality of semiconductor layers for electronics comprising InP HBTs (electronics layers), and a second plurality of semiconductor layers (photonics layers) for first and second vertically stacked optical waveguides WG1 and WG2. The first optical waveguide is structured for fabrication of an EAM, and the second optical waveguide is structured for fabrication of a laser diode.

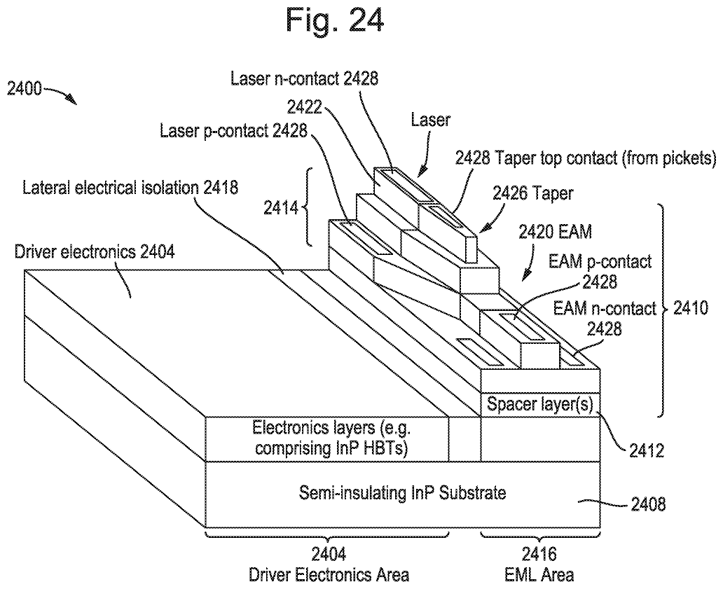

FIG. 24 is a schematic perspective view of a monolithic electro-photonic integrated circuit comprising an EML and driver electronics. The EAM driver electronics are fabricated on a first area of the substrate (Driver Electronics Area). The photonics layers and spacer are removed from the Driver Electronics Area. The EML waveguide structure is fabricated on a second area of the substrate (EAM area), overlying part of the electronics layer, and isolated therefrom by the spacer layers. Lateral electrical isolation is provided between the electronics layers (first plurality of semiconductor layers) underlying the EML waveguide structure and the electronics layers comprising HBTs of the EAM driver electronics. In the driver electronics area, the electronics layers are processed to define InP HBTs. Reference herein to HBTs is understood to include Single Heterostructure Bipolar Transistors (SHBTs) and Double Heterostructure Bipolar Transistors (DHBTs) and other types of HBTs. The photonics layers comprising WG1 and WG2 are processed, comprising etching to define the laser ridge and mesa, and the laterally tapered vertical optical coupler, and to define the mesa of the EAM waveguide comprising the passive waveguide region and the active region of the EAM. Electrical contacts are provided to the laser, to the taper, and to the EAM. One or more metallization layers and intermetal dielectric layers (not illustrated) provide electrical connections between the electronics and photonics (e.g. EAM driver and EAM connections, and laser driver and laser connections). Metallization and dielectric layers can be used to form other electronic components such as resistors, inductors, and capacitors. After fabrication of the above structure, one or more metallization layers and intermetal dielectric layers (not illustrated) provide electrical connections between the electronics and photonics (e.g. EAM driver and EAM connections, and laser driver and laser connections). Metallization and dielectric layers can be used to form other electronic components such as resistors, inductors, capacitors. Interconnects between photonics and electronics components are preferably provided by lithographically defined conductive metal traces, minimizing length of electrical connections to reduce interconnect parasitics (R, L, C).

For example, the above referenced U.S. patent application Ser. No. 19/089,534 discloses example process steps for fabrication of monolithically integrated EML of some example embodiments, with and without integrated electronics. Generally, the epitaxial layer stack comprises a plurality of semiconductor layers which are structured to form a plurality of vertically stacked optical waveguides, e.g. as illustrated in FIG. 23, configured for MGVI using one or more laterally tapered vertical optical couplers to optically couple the plurality of vertically stacked optical waveguides. For example, the plurality of vertically stacked optical waveguides comprise an EAM waveguide and a laser waveguide. After processing, the laser waveguide is horizontally displaced relative to the active EAM region of the EAM waveguide, e.g. in a stepped configuration. The semiconductor layers of the EAM waveguide may be vertically positioned or displaced above or below the semiconductor layers of the laser waveguide, so that the optical axes of the laser waveguide and the EAM are separated vertically, and the laser waveguide and the EAM waveguide are optically coupled by a laterally tapered vertical optical coupler. Optionally, the plurality of vertically stacked optical waveguides may comprise a passive output waveguide, e.g. as illustrated schematically in FIG. 21A and FIG. 21B. The passive output waveguide may be part of the second optical waveguide, laterally coupled to the output of the EAM. The passive output waveguide may be a third optical waveguide vertically stacked relative to the EAM waveguide, and a second lateral optical coupler is configured to couple an output of the EAM to the passive output waveguide. Optionally, the passive output waveguide may comprise a spot size converter.

The MQW layers can be fabricated using Metal-Organic Chemical Vapour Deposition (MOCVD), Molecular Beam Epitaxy (MBE) or other growth techniques. The strength of the excitonic binding energy for QCSE can be affected by the choice and specific implementation parameters of the growth technique. Control of the dopant for the n-layers and the p-layers provides for adjusting the capacitance. Typical MOCVD growths use Zn as the p-type dopant. M BE can provide Be as the p-type dopant, which is an advantage because Be is less mobile than Zn. This allows the junction with the i-region to be more abrupt, so that the p-i-n structure is defined to be more manufacturable.

To provide accurate control and fidelity of E-field, it is preferable to use M BE over MOCVD for fabrication, to provide more abrupt junctions. Use of a low physical mobility p-type dopant, e.g. Be rather than Zn, or C if possible, provides for a one-sided abrupt junction, and low-unintentionally doped intrinsic region. Diffusion of the n-type dopant, e.g. Si, is not usually an issue. Well defined junctions allow for a near-constant E-field across the intrinsic region, very little voltage drop outside the intrinsic region, and very little optical coupling outside the intrinsic region. Optical coupling outside the intrinsic region would lead to loss or, worse, diffusion tails.

Fabrication on an SI substrate with vertically coupled optical waveguides, using a single epitaxial growth or multiple epitaxial growth process, allows for integration of driver and control electronics, for reduced interconnect resistances, inductances and other parasitic capacitances, resistances and inductances. For example, the metallization and pad capacitances are reduced. Vertically integrated EML of example embodiments are based on vertically-coupled optical waveguides fabricated with a single growth process, wherein the laser has a surface etched grating. In some embodiments the laser waveguide has a buried (embedded/floating) grating which requires a secondary epitaxial growth after etching the grating. It is observed that a SI substrate significantly improves performance of both the laser diode and EAM., e.g. due to reduced device capacitance. This is because in a conventional structure, a doped conductive substrate and large backside electrical contact introduces significant parasitic capacitance.

A SI substrate is also required for use of a differential EAM driver. When fabricated on a SI substrate, the EAM is inherently differential, having first and second electrical contact pads that can be configured to be differentially driven, either using two single ended (SE) EAM drivers or a differential EAM driver. For example, the above referenced U.S. provisional patent application no. 63/754,106, entitled “Differential Electro-absorption Modulator System”, which is incorporated herein by reference in its entirety, discloses some examples of SE and differential EAM driver circuits, which may be hybrid integrated or monolithically integrated with an EAM. For example, FIG. 27 is a circuit schematic of an EAM and a differential EAM driver circuit of an example embodiment which is monolithically integrated on a single die. A differential DSP is connected to differential inputs of the EAM driver circuit. The EAM driver is a conventional differential driver with a bias T. In this example, the capacitors and bias inductors are monolithically integrated on the chip. The EAM is shown with a parallel load resistor. A load resistor in parallel with the EAM is used for RC matching, for both single-ended and differential EAM driver configurations. Differential pads for a differential EAM driver are more easily implemented for an EAM fabricated on a SI substrate.

The DFB grating can be a uniform grating or can have a phase shifted design. The phase shift can be a single-phase shift or a distributed phase shift. There can be a combination of uniform gratings and phase shifted gratings. For example, a λ/4 phase shifted DFB laser provides high slope efficiency (SE) with high single mode stability. DFB lasers of example embodiments with a λ/4 phase shifted gratings have demonstrated a very high SE (e.g. of the order of >0.5 A/W).

The device topology, i.e. physical layout over the device area, of the optoelectronic components and the electronic circuitry may be selected to optimize interconnect, improve thermal dissipation, make efficient use of the device area, et al. Thus, where feasible, various elements of the EML of the exemplary embodiments may be combined to provide additional or alternative embodiments. Referring to the schematic plan view shown in FIG. 2B, in the EML 200 of the second embodiment, the DFB laser control circuitry and EAM driver and control circuitry are shown schematically as positioned laterally of the EML. In other embodiments (not illustrated) the driver electronics may be positioned on an area spaced longitudinally from the EML waveguide structures, e.g. behind the back facet of the DFB laser. A back facet power monitor for the laser, i.e. a pin diode detector (not illustrated in the Figures) may be included. In practice, the integrated electronic circuitry may be positioned on the SI substrate around the EML as appropriate, e.g. to optimize interconnect, distribute heat generation from the electronics, and to optimize use of the device area. Beneficially, the integrated EAM driver circuitry is positioned in close proximity to the EAM to minimize interconnect lengths, e.g. to reduce interconnect parasitics and enable higher performance modulation. In some embodiments the EML is monolithically integrated with the EAM driver and control electronics, while other electronics, e.g. the laser driver, monitoring and control circuitry, are provided on a separate chip. In some embodiments, the integrated electronics includes a laser driver as well as the EAM driver. In other embodiments based on the monolithically integrated EML structure shown in FIGS. 1A and 1B, without integrated electronics, the laser and EAM driver and control electronics are provided as separate chips.

As illustrated by the example embodiments, a vertically integrated EML may be fabricated with or without integrated driver and control electronics. Advantageously, at least the EAM driver and control electronics are also vertically integrated into the device structure, e.g. to optimize interconnect from the EAM driver to the EAM, e.g. reduce interconnect length, inductance, resistance, etc., to enable reliable, higher performance modulation of the EAM, e.g. PAM 4. The DFB laser is operated in CW mode, so close proximity of the laser driver and control electronics may not be as important, but optionally the integrated electronic circuitry includes a laser driver. Optionally, other electrical and optical components, e.g. a temperature sensor, optical detector for power monitoring, et al., may be monolithically integrated, as appropriate. Electrical interconnections are provided by one or more metallization layers and intermetal dielectric layers. The metallization and dielectric layers may also be structured to provide other electrical components such as resistors, capacitors and inductors.

Another consideration is thermal dissipation. Thermal conductivity of a SI InP substrate is lower than the thermal conductivity of an n-doped InP substrate. So another trade-off is thermal resistance, which can be managed by providing suitable thermal management, e.g. a heat-spreader, cooling, thinning of the substrate and transfer/bonding to a thermally conductive substrate to provide a suitable thermally conductive sub-mount. The thermally conductive substrate may a material such as, aluminum oxide, aluminum nitride or other thermally conductive ceramic material, with a suitable coefficient of thermal expansion (CTE). Alternatively, the EML may be mounted up-side down, flipped and bonded to a thermal substrate for heat dissipation. Or part of the substrate may be etched away to allow for insertion of a thermal slug or thermally conductive inlay.

The DFB laser and the EAM have different thermal coefficients. For example, the wavelength thermal coefficient of a DFB laser is approximately 0.1 nm/C and the wavelength thermal coefficient of the QCSE layer structure of the EAM is approximately 0.6 nm/C. The laser exhibits self-heating related to the current passing through (I_laser), the bias on the laser (V_laser) and the material thermal coefficient of the III-V materials in aggregate (e.g. InP has a thermal coefficient of 68 mW/K; other III-V layers have different thermal coefficients). Additionally, a load resistor in parallel with the EAM is used for RC matching, for both single-ended and differential EAM driver configurations. The load resistor acts as heater to heat the EAM. Additionally, a load resistor adds heat to the laser due to material thermal conduction. The detuning of the laser from the EAM needs to take into account the temperature of the laser, the temperature of the EAM based on material thermal transfer, and the detuning between the laser PL peak and EAM PL peak for effective EAM operation relative to the laser wavelength. In some cases, an on-chip heater comprising a load resistor is provided to heat the EAM. This can be a load resistor for optimized impedance matching which also performs a heat control function. For example, if the laser temperature increases 30 C, increasing the temperature of the EAM by 5 C would match the wavelength detuning of the laser.

Some thermal separation between the laser and the EAM is provided by the distance between the laser and the active region of the EAM created by the length of the laterally tapered vertical optical coupler, and a length of a passive region of the EAM waveguide between the end of the taper and the active region of the EAM. There may be a trade-off between optical losses from longer tapers and longer passive coupling waveguides vs. thermal separation.

Monolithically integrated EML of some exemplary embodiments have been described by way example. In each of the exemplary embodiments, vertical integration of a DFB laser and EAM through a laterally tapered vertically optical coupler, based on MGVI fabrication, provides for integration of these components in a device structure that may provide increased reliability compared to conventional butt-coupling of a DFB laser and EAM. In example embodiments, a balancing layer, comprising a quaternary material having a higher refractive index, is positioned above or below the DFB grating in the epitaxial stack for the DFB laser. The balancing layer, in combination with design of the laterally tapered vertical optical coupler, allows for efficient control of laser mode confinement, distributed feedback coupling and control of optical mode transfer between the DFB laser waveguide and the EAM waveguide.

It is recognized that a directly-or indirectly-butt-coupled interface between a DFB laser and EAM results in an interface with high stress and strain, which may result in reliability issues, or premature failure, particularly under higher power operation. The structure of the laterally-tapered vertical optical couplers of the EML of the exemplary embodiments provides efficient vertical optical coupling between the output of the DFB laser and the input of the EAM. The epi-layer structure for the vertically integrated waveguides for the DFB laser and EAM can be designed to reduce stress/strain between the optical components, and the vertically integrated EML avoids a high stress/strain interface region between a conventionally butt-coupled DFB laser and EAM.

It will be noted that all measurements mentioned in the specification are indicated as examples and other similar values could apply without limitation.

Although example embodiments have been described and illustrated in detail, it is to be clearly understood that the same is by way of illustration and example only and not to be taken by way of limitation, the scope of the present invention being limited only by the appended claims.

1. The monolithically integrated EML of claim 2, wherein the DFB laser comprises a mesa and a ridge, and the DFB grating is within the ridge, and the balancing layer is within the ridge below the DFB grating and separated from the DFB grating by a spacer layer.

2. The monolithically integrated EML of claim 2, wherein the DFB laser comprises a mesa and a ridge, and the DFB grating is positioned within the mesa, and the balancing layer is within the ridge above the DFB grating and separated from the DFB grating by a spacer layer, and the balancing layer has a width less than a width of the ridge.

3. The monolithically integrated EML of claim 2, wherein the DFB laser comprises a mesa and a ridge, and the DFB grating is positioned within the mesa, and the balancing layer is within the mesa, above or below the DFB grating.

4. The monolithically integrated EML of claim 2, comprising third electrical connections to at least part of the laterally tapered vertical optical coupler for biasing the laterally tapered vertical optical coupler.

5. The monolithically integrated EML of claim 14, wherein the third electrical connections comprise a plurality of conductive traces extending laterally across said at least part of the laterally tapered vertical optical coupler.

6. The monolithically integrated EML of claim 2, wherein the laterally tapered vertical optical coupler comprises a first section defined by sidewalls of the second optical waveguide and a second section defined by sidewalls of the first optical waveguide.

7. The monolithically integrated EML of claim 14, wherein the laterally tapered vertical optical coupler comprises a first section defined by sidewalls of the second optical waveguide, and a second section defined by sidewalls of the first optical waveguide, wherein the sidewalls of the first optical waveguide are defined by a trench etched through layers of the first optical waveguide.

8. The monolithically integrated EML of claim 17, wherein the trench is discontinuous to provide bridges for routing of said third electrical connections.

9. The monolithically integrated EML of claim 2, comprising a passive transition waveguide disposed between the first optical waveguide and the second optical waveguide, the passive transition waveguide comprising a second laterally tapered vertical optical coupler, the optical output of the DFB laser being optically coupled from the laterally tapered vertical optical coupler of the second optical waveguide to the passive transition waveguide and from the second laterally tapered vertical optical coupler through the passive transition waveguide to the first optical wavequide to the input of the EAM.

10. The monolithically integrated EML of claim 19, wherein the first optical waveguide has an effective refractive index greater than the effective refractive index of the second optical waveguide, and the passive transition waveguide has a non-absorbing core of a material that provides an effective refractive index of the passive transition waveguide having a value between the effective refractive indexes of the first optical waveguide and the second optical waveguide.

11. The monolithically integrated EML of claim 2, wherein an output of the EAM is optically coupled to a passive output waveguide.

12. The monolithically integrated EML of claim 2, fabricated with III-V semiconductor materials.

13. The monolithically integrated EML of claim 2, wherein the SI substrate is Fe-doped InP and EML is fabricated from an InP-based material system, comprising selected binary, ternary and quaternary and other compositions of In, Ga, As, P, Al and Sb.

14. The monolithically integrated EML of claim 23, wherein the upper and lower cladding layers of the second optical waveguide comprise Indium Phosphide (InP), and the balancing layer comprises a material that is substantially lattice matched to InP, wherein the refractive index of the balancing layer is greater than the refractive index of InP.

15. The monolithically integrated EML of claim 24, wherein the balancing layer is a layer of a quaternary material, comprising one of InGaAlAs and InGaAsP.

16. The monolithically integrated EML of claim 2, comprising a second plurality of semiconductor layers formed on the SI substrate comprising electronic circuitry, the electronic circuitry comprising an EAM driver, and the EAM driver being electrically connected to the second electrical connections of the EAM and configured to drive the EAM to provide a modulated optical output.

17. The monolithically integrated EML of claim 26, wherein the electronic circuitry comprises a laser driver, the laser driver being electrically connected to the first electrical connections of the DEB laser and configured to drive the DFB laser.

28. The EML of claim 2, wherein the balancing layer thickness is in a range of 80 nm to 100 nm.

29. A monolithically integrated electro-absorption modulated laser (EML) comprising:
a semi-insulating (SI) substrate;
a plurality of semiconductor layers formed on the SI substrate defining a first optical waveguide and a second optical waveguide that are vertically stacked;
a part of the first optical waveguide comprising an electro-absorption modulator (EAM) having a core comprising a first multi-quantum well (MQW) i-region, and upper and lower cladding layers;
the second optical waveguide having a core comprising a second MQW i-region, and upper and lower cladding layers, a first part of the second optical waveguide defining a distributed feedback (DFB) laser comprising a DFB grating, and second part of WG2 defining a laterally tapered vertical optical coupler extending from an optical output of the DFB laser;
the laterally tapered vertical optical coupler being structured to couple an optical mode from the optical output of the DFB laser to an input of the EAM;
first electrical connections to the DFB laser configured for operating the DFB laser in continuous wave (CW) mode;
second electrical connections to the EAM configured for driving the EAM; and
a balancing layer extending within upper cladding layers of the second optical waveguide, along a length of DFB laser and the laterally tapered vertical optical coupler, above the second MQW i-region, the balancing layer being spaced from the DFB grating, the balancing layer comprising a material having a refractive index and a thickness selected to control a relative confinement of said optical mode in the core of the DFB laser and said optical mode in the core of the EAM and to control a DFB coupling coefficient κ.
